(19) United States
(12) Patent Application Publication
(10) Pub. No.: US 2024/0096808 A1
(43) Pub. Date: Mar. 21, 2024

(54) SEMICONDUCTOR PACKAGE, MANUFACTURING METHOD OF SEMICONDUCTOR PACKAGE, AND INTERPOSER GROUP

(71) Applicant: DAI NIPPON PRINTING CO., LTD., Tokyo (JP)

(72) Inventors: Hiroshi KUDO, Tokyo (JP); Takamasa TAKANO, Tokyo (JP)

(21) Appl. No.: 18/264,281

(22) PCT Filed: Jan. 31, 2022
(86) PCT No.: PCT/JP2022/003672

§ 371 Date: Aug. 4, 2023

(30) Foreign Application Priority Data
Feb. 5, 2021 (JP) 2021-017623

(51) Int. Cl. H01L 23/538; H01L 23/00; H01L 23/48; H01L 25/00; H01L 25/065

(52) U.S. Cl. CPC H01L 23/5385; H01L 23/481; H01L 23/5381; H01L 23/5383; H01L 24/16; H01L 25/0655; H01L 25/50; H01L 24/32; H01L 24/73; H01L 2224/16227; H01L 2224/32225; H01L 2224/73204

(57) ABSTRACT

A semiconductor package includes a first interposer that includes a first face and a second face, a second interposer that includes a third face and a fourth face, and that is arrayed with the first interposer in a first direction, a third interposer that includes a fifth face and a sixth face, and that is situated between the first interposer and the second interposer in the first direction, a first semiconductor element that overlaps the first face and the fifth face in plan view, and a second semiconductor element that overlaps the third face and the fifth face in plan view. The third interposer includes wiring that electrically connects the first semiconductor element and the second semiconductor element.

### TECHNICAL FIELD

An embodiment of the present disclosure relates to a semiconductor package, a manufacturing method of the semiconductor package, and an interposer group.

### BACKGROUND ART

There is known three-dimensional packaging technology in which a plurality of semiconductor elements that have integrated circuits are combined. In the three-dimensional packaging technology, substrates that have through vias are used. Such substrates that have through vias are also referred to as interposers. For example, PTL 1 and 2 disclose semiconductor packages having interposers including through vias or wiring, and semiconductor elements mounted on the interposers.

### CITATION LIST

### Patent Literature

PTL 1: Japanese Patent No. 6014907
PTL 2: Japanese Patent No. 6159820

### SUMMARY OF INVENTION

The greater the number of semiconductor elements included in a semiconductor package is, the higher the performance of the semiconductor package is. On the other hand, the dimensions of the interposers increase. The greater the dimensions of the interposers are, the more readily deformation such as warping and so forth occurs in the interposers.

It is an object of an embodiment according to the present disclosure to provide a semiconductor package and an interposer group that can effectively solve such problems.

An embodiment of the present disclosure is a semiconductor package including
a first interposer that includes a first face and a second face situated on an opposite side from the first face,
a second interposer that includes a third face and a fourth face situated on an opposite side from the third face, and that is arrayed with the first interposer in a first direction,
a third interposer that includes a fifth face and a sixth face situated on an opposite side from the fifth face, and that is situated between the first interposer and the second interposer in the first direction,
a first semiconductor element that overlaps the first face and the fifth face in plan view, and
a second semiconductor element that overlaps the third face and the fifth face in plan view.

The third interposer includes wiring that electrically connects the first semiconductor element and the second semiconductor element.

In the semiconductor package according to an embodiment of the present disclosure,
the first interposer may include a first cavity, and
the semiconductor package may further include a first internal semiconductor element that is situated in the first cavity.

In the semiconductor package according to an embodiment of the present disclosure,
the first cavity may be formed in the first face, and
the first internal semiconductor element may be electrically connected to the first semiconductor element.

In the semiconductor package according to an embodiment of the present disclosure,
the second interposer may include a second cavity, and
the semiconductor package may further include a second internal semiconductor element that is situated in the second cavity.

In the semiconductor package according to an embodiment of the present disclosure,
the second cavity may be formed in the third face, and
the second internal semiconductor element may be electrically connected to the second semiconductor element.

The semiconductor package according to an embodiment of the present disclosure may further include a third semiconductor element that overlaps the second face, the fourth face, and the sixth face in plan view.

The semiconductor package according to an embodiment of the present disclosure may further include a wiring substrate that includes a substrate and a pad that is electrically connected to the third semiconductor element.

In the semiconductor package according to an embodiment of the present disclosure, the substrate may contain an organic material.

In the semiconductor package according to an embodiment of the present disclosure, the first interposer may include a cavity formed in the second face, and the semiconductor package may further include a first internal element that is situated in the cavity formed in the second face and that is electrically connected to the third semiconductor element.

In the semiconductor package according to an embodiment of the present disclosure,
the second interposer may include a cavity formed in the fourth face, and
the semiconductor package may further include a second internal element that is situated in the cavity formed in the fourth face and that is electrically connected to the third semiconductor element.

In the semiconductor package according to an embodiment of the present disclosure, the first interposer may include a first through via.

In the semiconductor package according to an embodiment of the present disclosure, the second interposer may include a second through via.

In the semiconductor package according to an embodiment of the present disclosure, the third interposer may include a third through via.

In the semiconductor package according to an embodiment of the present disclosure,
the third interposer may include a redistribution layer that is situated on the fifth face, and that includes an insulating layer and wiring, and
the insulating layer may contain an organic insulating material.

In the semiconductor package according to an embodiment of the present disclosure, the organic insulating material may contain polyimide, epoxy-based resin, or acrylic-based resin.

In the semiconductor package according to an embodiment of the present disclosure, the insulating layer may contain a filler made of an inorganic material.

In the semiconductor package according to an embodiment of the present disclosure,
the first interposer may include a first substrate made of an inorganic material,
an insulating layer containing an organic insulating material may not be provided on the faces of the first substrate of the first interposer,
the second interposer may include a second substrate made of an inorganic material, and
an insulating layer containing an organic insulating material may not be provided on the faces of the second substrate of the second interposer.

In the semiconductor package according to an embodiment of the present disclosure,
the first interposer may include a first substrate made of an inorganic material, and a redistribution layer that is situated on one of the faces of the first substrate and that includes an insulating layer and wiring, and
the second interposer may include a second substrate made of an inorganic material, and a redistribution layer that is situated on one of the faces of the second substrate and that includes an insulating layer and wiring.

An embodiment of the present disclosure is a manufacturing method of a semiconductor package. The manufacturing method includes
a disposing step of disposing a first interposer that includes a first face and a second face situated on an opposite side from the first face, a second interposer that includes a third face and a fourth face situated on an opposite side from the third face, and a third interposer that includes a fifth face and a sixth face situated on an opposite side from the fifth face,
a first mounting step of mounting a first semiconductor element so as to overlap the first face and the fifth face in plan view, and
a second mounting step of mounting a second semiconductor element so as to overlap the third face and the fifth face in plan view.

The second interposer is arrayed with the first interposer in a first direction.

The third interposer is situated between the first interposer and the second interposer in the first direction.

The third interposer includes wiring that electrically connects the first semiconductor element and the second semiconductor element.

In the manufacturing method of the semiconductor package according to an embodiment of the present disclosure,
the first interposer may include a first cavity, and
the first mounting step may include a step of disposing, in the first cavity, a first internal semiconductor element that is connected to the first semiconductor element.

In the manufacturing method of the semiconductor package according to an embodiment of the present disclosure,
the second interposer may include a second cavity, and
the second mounting step may include a step of disposing, in the second cavity, a second internal semiconductor element that is connected to the second semiconductor element.

The manufacturing method of the semiconductor package according to an embodiment of the present disclosure may further include a preparation step of preparing a third semiconductor element.

In the disposing step, the first interposer, the second interposer, and the third interposer may be disposed such that the second face, the fourth face, and the sixth face overlap the third semiconductor element in plan view.

The manufacturing method of the semiconductor package according to an embodiment of the present disclosure may further include a step of disposing a wiring substrate including a substrate and a pad, such that the pad of the wiring substrate is electrically connected to the third semiconductor element.

The manufacturing method of the semiconductor package according to an embodiment of the present disclosure may further include a step of mounting a first internal element in the third semiconductor element.

The disposing step may include a step of disposing the first interposer such that the first internal element is situated in a cavity formed in the second face.

In the manufacturing method of the semiconductor package according to an embodiment of the present disclosure, the first interposer may include a first through via.

An embodiment of the present disclosure is an interposer group onto which a first semiconductor element and a second semiconductor element are mounted. The interposer group includes
a first interposer that includes a first face and a second face situated on an opposite side from the first face,
a second interposer that includes a third face and a fourth face situated on an opposite side from the third face, and that is arrayed with the first interposer in a first direction, and
a third interposer that includes a fifth face and a sixth face situated on an opposite side from the fifth face, and that is situated between the first interposer and the second interposer in the first direction.

The first semiconductor element is mounted so as to overlap the first face and the fifth face in plan view.

The second semiconductor element is mounted so as to overlap the third face and the fifth face in plan view.

The third interposer includes wiring that electrically connects the first semiconductor element and the second semiconductor element.

According to an embodiment of the present disclosure, deformation such as warping and so forth can be suppressed from occurring in the interposers.

### BRIEF DESCRIPTION OF DRAWINGS

FIG. 1 is a plan view illustrating a semiconductor package according to a first embodiment.

FIG. 2 is a sectional view taken along line A-A of the semiconductor package in FIG. 1.

FIG. 3 is a sectional view illustrating a first interposer in FIG. 2 in an enlarged manner.

FIG. 4 is a sectional view illustrating a third interposer in FIG. 2 in an enlarged manner.

FIG. 5 is a sectional view illustrating wiring of the third interposer in FIG. 4 in an enlarged manner.

FIG. 6 is a diagram schematically illustrating warping occurring in a comparative embodiment.

FIG. 7 is a diagram schematically illustrating warping occurring in the first embodiment.

FIG. 8 is a diagram for describing a manufacturing method of the semiconductor package.

FIG. 9 is a diagram for describing the manufacturing method of the semiconductor package.

FIG. 10 is a diagram for describing the manufacturing method of the semiconductor package.

FIG. 11 is a diagram for describing the manufacturing method of the semiconductor package.

FIG. 12 is a diagram for describing the manufacturing method of the semiconductor package.

FIG. 13 is a diagram for describing the manufacturing method of the semiconductor package.

FIG. 14 is a diagram for describing the manufacturing method of the semiconductor package.

FIG. 15 is a diagram for describing the manufacturing method of the semiconductor package.

FIG. 16 is a diagram for describing the manufacturing method of the semiconductor package.

FIG. 17 is a diagram for describing the manufacturing method of the semiconductor package.

FIG. 18 is a diagram for describing the manufacturing method of the semiconductor package.

FIG. 19 is a plan view illustrating a semiconductor package according to a second embodiment.

FIG. 20 is a sectional view taken along line B-B of the semiconductor package in FIG. 19.

FIG. 21 is a sectional view illustrating a first interposer in FIG. 20 in an enlarged manner.

FIG. 22 is a diagram for describing a manufacturing method of the semiconductor package.

FIG. 23 is a diagram for describing the manufacturing method of the semiconductor package.

FIG. 24 is a diagram for describing the manufacturing method of the semiconductor package.

FIG. 25 is a diagram for describing the manufacturing method of the semiconductor package.

FIG. 26 is a diagram for describing the manufacturing method of the semiconductor package.

FIG. 27 is a diagram for describing the manufacturing method of the semiconductor package.

FIG. 28 is a diagram for describing the manufacturing method of the semiconductor package.

FIG. 29 is a diagram for describing the manufacturing method of the semiconductor package.

FIG. 30 is a diagram for describing the manufacturing method of the semiconductor package.

FIG. 31 is a diagram for describing the manufacturing method of the semiconductor package.

FIG. 32 is a diagram for describing the manufacturing method of the semiconductor package.

FIG. 33 is a diagram for describing the manufacturing method of the semiconductor package.

FIG. 34 is a diagram for describing the manufacturing method of the semiconductor package.

FIG. 35 is a diagram for describing the manufacturing method of the semiconductor package.

FIG. 36 is a sectional view illustrating a semiconductor package according to a third embodiment.

FIG. 37 is a sectional view illustrating a semiconductor package according to a fourth embodiment.

FIG. 38 is a sectional view illustrating a semiconductor package according to a fifth embodiment.

FIG. 39 is a sectional view illustrating an example of through vias.

FIG. 40 is a sectional view illustrating an example of the through vias.

FIG. 41 is a diagram illustrating an example of products in which the semiconductor package is mounted.

FIG. 42 is a diagram showing results of a thermal cycle test performed on Example 1 and Comparative Example 1.

FIG. 43 is a diagram showing results of a thermal cycle test performed on Example 2 and Comparative Example 2.

FIG. 44 is a sectional view illustrating an example of a semiconductor package according to a sixth embodiment.

FIG. 45 is a sectional view illustrating an example of the semiconductor package according to the sixth embodiment.

FIG. 46 is a sectional view illustrating an example of a semiconductor package according to a seventh embodiment.

FIG. 47 is a sectional view illustrating an example of the semiconductor package according to the seventh embodiment.

FIG. 48A is a sectional view illustrating an example of a semiconductor package according to an eighth embodiment.

FIG. 48B is a sectional view illustrating an example of the semiconductor package according to the eighth embodiment.

FIG. 49 is a sectional view illustrating an example of the semiconductor package according to the eighth embodiment.

FIG. 50 is a sectional view illustrating an example of a semiconductor package according to a ninth embodiment.

FIG. 51 is a sectional view illustrating an example of the semiconductor package according to the ninth embodiment.

FIG. 52 is a sectional view illustrating an example of a semiconductor package according to a tenth embodiment.

FIG. 53 is a sectional view illustrating an example of the semiconductor package according to the tenth embodiment.

FIG. 54A is a diagram for describing an example of a method of forming a redistribution layer.

FIG. 54B is a diagram for describing an example of the method of forming the redistribution layer.

FIG. 54C is a diagram for describing an example of the method of forming the redistribution layer.

FIG. 54D is a diagram for describing an example of the method of forming the redistribution layer.

FIG. 54E is a diagram for describing an example of the method of forming the redistribution layer.

FIG. 54F is a diagram for describing an example of the method of forming the redistribution layer.

FIG. 54G is a diagram for describing an example of the method of forming the redistribution layer.

FIG. 54H is a diagram for describing an example of the method of forming the redistribution layer.

FIG. 54I is a diagram for describing an example of the method of forming the redistribution layer.

FIG. 54J is a diagram for describing an example of the method of forming the redistribution layer.

FIG. 54K is a diagram for describing an example of the method of forming the redistribution layer.

FIG. 54L is a diagram for describing an example of the method of forming the redistribution layer.

FIG. 55A is a diagram for describing an example of a method for connecting the redistribution layer to a first semiconductor element.

FIG. 55B is a diagram for describing an example of a method for connecting the redistribution layer to the first semiconductor element.

FIG. 56 is a plan view illustrating a stacked assembly according to Comparative Example 3.

FIG. 57 is a sectional view illustrating the stacked assembly according to Comparative Example 3.

FIG. 58 is a plan view illustrating a stacked assembly according to Example 3.

FIG. 59 is a sectional view illustrating the stacked assembly according to Example 3.

### DESCRIPTION OF EMBODIMENTS

A configuration of a semiconductor package and a manufacturing method thereof will be described in detail below with reference to the drawings. Note that the embodiments illustrated below are examples of embodiments of the present disclosure, and that the present disclosure is not to be interpreted to be limited to these embodiments. In the present specification, terms such as “substrate”, “base material”, “sheet”, “film”, and so forth, are not distinguished from each other on the basis of difference in naming alone. For example, “substrate” is a concept including members that can be called sheet or film. “Face” means a face that matches a planar direction of a plate-like member that is an object, when the plate-like member that is the object is viewed fully and comprehensively. A direction normal to a plate-like member means the direction normal to a face of the plate-like member. Terms such as “parallel”, “orthogonal”, and so forth, and values of length and angle, and so forth, used to identify shapes and geometric conditions and the extent thereof in the present specification, for example, are to be interpreted so as to include a range of an extent in which similar functions can be anticipated, without being bound by the strict meaning thereof.

In the present specification, in a case in which a plurality of candidates for an upper limit value and a plurality of candidates for a lower limit value are given regarding a certain parameter, the numeral value range of the parameter may be made up of a combination of any one upper limit value candidate and any one lower limit value candidate. For example, a case in which description is made that “Parameter B is, for example, A1 or more, and may be A2 or more, and may be A3 or more. Parameter B is, for example, A4 or less, and may be A5 or less, and may be A6 or less.” will be considered. In this case, the numerical value range of parameter B may be A1 or more and A4 or less, may be A1 or more and A5 or less, may be A1 or more and A6 or less, may be A2 or more and A4 or less, may be A2 or more and A5 or less, may be A2 or more and A6 or less, may be A3 or more and A4 or less, may be A3 or more and A5 or less, or may be A3 or more and A6 or less.

In the drawings referenced in the present embodiment, parts that are the same parts or parts having similar functions are denoted by the same signs or similar signs, and repetitive description thereof may be omitted in some cases. Also, there are cases in which the dimensional ratios in the drawings differ from the actual ratio, for sake of convenience, and part of configurations may be omitted from the drawings.

### First Embodiment

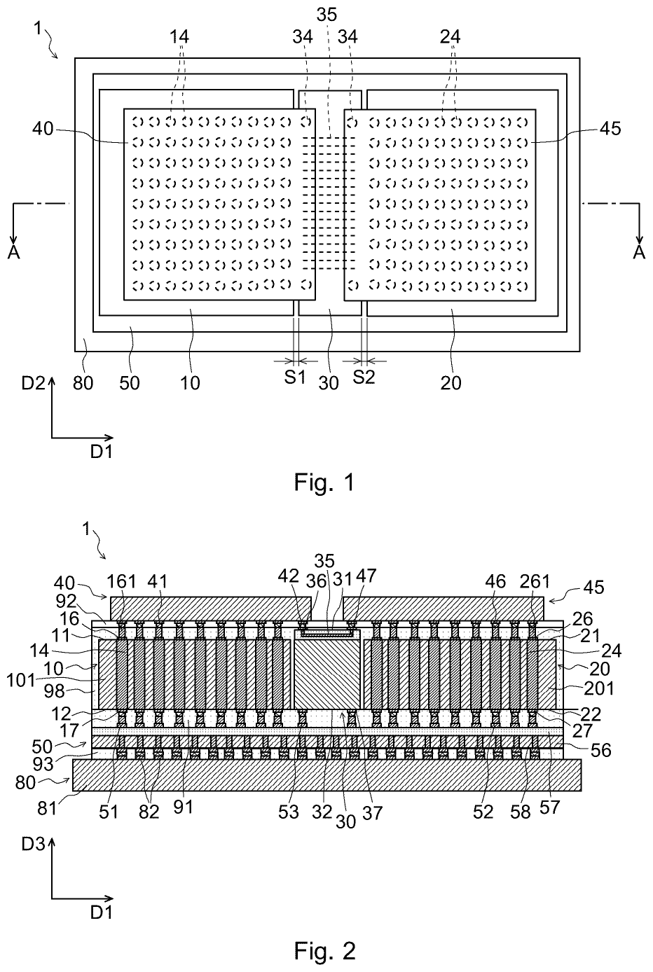

FIG. 1 is a plan view illustrating a semiconductor package 1 according to a first embodiment. The semiconductor package 1 has a first direction D1, a second direction D2, and a third direction D3. The first direction D1 and the second direction D2 are included in a planar direction of the semiconductor package 1. The first direction D1 is orthogonal to the second direction D2. The third direction D3 is the thickness direction of the semiconductor package 1. The third direction D3 is orthogonal to the first direction D1 and the second direction D2.

The semiconductor package 1 includes a first interposer 10, a second interposer 20, a third interposer 30, a first semiconductor element 40, a second semiconductor element 45, and a third semiconductor element 50. As illustrated in FIG. 1, the first interposer 10, the second interposer 20, and the third interposer 30 are arrayed in the first direction D1. The third interposer 30 is situated between the first interposer 10 and the second interposer 20 in the first direction D1.

As illustrated in FIG. 1, the first semiconductor element 40 is mounted on the first interposer 10 and the third interposer 30. Specifically, the first semiconductor element 40 is electrically connected to both of the first interposer 10 and the third interposer 30. For example, the first interposer 10 includes through vias 14 that are electrically connected to the first semiconductor element 40. The third interposer 30 includes wiring 35 that is electrically connected to the first semiconductor element 40. The third interposer 30 may include through vias 34 that are electrically connected to the first semiconductor element 40. In the description below, the through vias 14 of the first interposer 10 may also be referred to as first through vias 14, and the through vias 34 of the third interposer 30 may also be referred to as third through vias 34.

As illustrated in FIG. 1, the second semiconductor element 45 is mounted on the second interposer 20 and the third interposer 30. Specifically, the second semiconductor element 45 is electrically connected to both of the second interposer 20 and the third interposer 30. For example, the second interposer 20 includes through vias 24 that are electrically connected to the second semiconductor element 45. In the description below, the through vias 24 of the second interposer 20 may also be referred to as second through vias 24. The third interposer 30 includes the wiring 35 that is electrically connected to the second semiconductor element 45. The wiring 35 electrically connects the first semiconductor element 40 and the second semiconductor element 45. The third interposer 30 may include the third through vias 34 that are electrically connected to the second semiconductor element 45.

A group of interposers on which the first semiconductor element 40 and the second semiconductor element 45 are mounted is also referred to as an interposer group. In the present embodiment, the first interposer 10, the second interposer 20, and the third interposer 30 make up the interposer group.

A spacing S1 between the first interposer 10 and the third interposer 30 in the first direction D1 is, for example, 0.03 mm or more, may be 0.05 mm or more, and may be 0.1 mm or more. The spacing S1 is, for example, 3.0 mm or less, may be 1.0 mm or less, and may be 0.5 mm or less.

The range of the spacing S1 described above may be employed as a range for a spacing S2 between the second interposer 20 and the third interposer 30 in the first direction D1.

FIG. 2 is a sectional view taken along line A-A of the semiconductor package 1 in FIG. 1. The first interposer 10 includes a first face 11 and a second face 12. The second face 12 is situated on an opposite side from the first face 11. The second interposer 20 includes a third face 21 and a fourth face 22. The fourth face 22 is situated on an opposite side from the third face 21. The third interposer 30 includes a fifth face 31 and a sixth face 32. The sixth face 32 is situated on an opposite side from the fifth face 31. The first face 11, the third face 21, and the fifth face 31, are situated on the same side. The second face 12, the fourth face 22, and the sixth face 32 are situated on the same side.

The first semiconductor element 40 is mounted on the first face 11 and the fifth face 31. Accordingly, the first semiconductor element 40 overlaps the first face 11 and the fifth face 31 in plan view. The second semiconductor element 45 is mounted on the third face 21 and the fifth face 31. Accordingly, the second semiconductor element 45 overlaps the third face 21 and the fifth face 31 in plan view. “In plan view” means viewing in the direction normal to the face of the member.

As illustrated in FIG. 1 and FIG. 2, the semiconductor package 1 may include the third semiconductor element 50. The first interposer 10, the second interposer 20, and the third interposer 30 may be mounted on the third semiconductor element 50. The third semiconductor element 50 faces the second face 12, the fourth face 22, and the sixth face 32. Accordingly, the third semiconductor element 50 overlaps the second face 12, the fourth face 22, and the sixth face 32 in plan view.

As illustrated in FIG. 1 and FIG. 2, the semiconductor package 1 may include a wiring substrate 80. The wiring substrate 80 may be electrically connected to the third semiconductor element 50.

The components of the semiconductor package 1 will be described in detail.

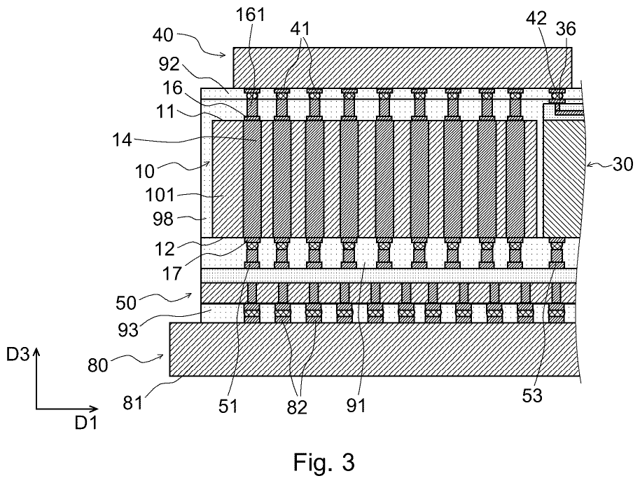

FIG. 3 is a sectional view illustrating the first interposer 10 in FIG. 2 in an enlarged manner. The first interposer 10 includes a substrate 101 and the first through vias 14 situated at positions of through holes passing through the substrate 101. The first through vias 14 have conductivity. The first interposer 10 may include pads 16 situated on the first face 11. The first interposer 10 may include pads 17 situated on the second face 12.

Although not illustrated, the first interposer 10 may include wiring and an insulating layer situated on the first face 11 and may include wiring and an insulating layer situated on the second face 12. In this case, the first face 11 and the second face 12 of the first interposer 10 may be made of the surfaces of the insulating layers. Resins such as polyimide, epoxy-based resin, acrylic-based resin, and so forth, can be used as the material making up the insulating layer.

The first interposer 10 does not have to include insulating layers situated on the first face 11 or the second face 12. For example, the first interposer 10 does not have to include insulating layers that are situated on the first face 11 or the second face 12 and that contain polyimide. That is to say, the surfaces of the substrate 101 do not have to be provided with insulating layers containing an organic insulating material. Accordingly, warping of the substrate 101 due to stress within the insulating layers can be suppressed. The substrate 101 of the first interposer 10 will also be referred to as first substrate 101.

The substrate 101 may be made of an inorganic material. For example, the substrate 101 is a glass substrate, a quartz substrate, a sapphire substrate, a resin substrate, a silicon substrate, a silicon carbide substrate, an alumina (Al2O3) substrate, an aluminum nitride (AlN) substrate, a zirconia oxide (ZrO2) substrate, a lithium niobate substrate, a tantalum niobate substrate, or the like, or a stacked assembly of these substrates. The substrate 101 may partially include a substrate made of a material having conductivity, such as an aluminum substrate, a stainless steel substrate, or the like. The thickness of the substrate 101 is, for example, 0.1 mm or more, may be 0.2 mm or more, and may be 0.5 mm or more. The thickness of the substrate 101 is, for example, 2.0 mm or less, may be 1.5 mm or less, and may be 1.0 mm or less.

The first through vias 14 extend from one face of the substrate 101 to the other face thereof in the through holes of the substrate 101. The first through vias 14 may be situated over the entire region of the through holes of the substrate 101. That is to say, the first through vias 14 may be so-called filled vias with which the through holes of the substrate 101 are filled. The first through vias 14 do not have to fill the through holes of the substrate 101, which will be described later.

The first through vias 14 may include a plurality of layers. For example, the first through vias 14 may include a first layer that is situated on side faces of the through holes of the substrate 101, and a second layer that is situated upon the first layer. The second layer may extend to the centers of the through holes of the substrate 101 in plan view.

The first layer is formed on the side faces of the through holes by physical film formation methods such as sputtering, vapor deposition, or the like, for example. The thickness of the first layer is, for example, 0.05 μm or more. The thickness of the first layer is 1.0 μm or less. Note that other layers may be provided between the first layer and the side faces of the through holes. Metals such as titanium, chromium, nickel, copper, and so forth, alloys using these, or layered arrangements thereof, can be used as the material making up the first layer.

The second layer may contain copper as a primary component. For example, the second layer may contain 80% by mass or more of copper. Also, the second layer may contain metals such as gold, silver, platinum, rhodium, tin, aluminum, nickel, chromium or the like, or alloys using these. The second layer is formed upon the first layer by electrolytic plating, for example.

The pads 16 and 17 include a conductive layer. As illustrated in FIG. 3, the pads 16 may be situated on the first through vias 14 on the first face 11 side. The pads 17 may be situated on the first through vias 14 on the second face 12 side. The materials listed with regard to the first through vias 14 may be used as the material making up the pads 16 and 17. The thickness of the pads 16 and 17 is, for example, 0.5 μm or more, and may be 1.0 μm or more. The thickness of the pads 16 and 17 is, for example, 10.0 μm or less, and may be 5.0 μm or less.

As illustrated in FIG. 3, pillars 161 may be formed on the pads 16. The thickness of the pillars 161 is greater than the thickness of the pads 16. The materials listed with regard to the first through vias 14 may be used as the material making up the pillars 161.

The second interposer 20 includes a substrate 201 and the second through vias 24 situated at position of through holes passing through the substrate 201. The second interposer 20 may include pads 26 situated on the third face 21. The second interposer 20 may include pads 27 situated on the fourth face 22. Pillars 261 may be formed on the pads 26. The second interposer 20 may include wiring and an insulating layer situated on the third face 21, and may include wiring and an insulating layer situated on the fourth face 22, although not illustrated. In this case, the third face 21 and the fourth face 22 of the second interposer 20 made of the surfaces of the insulating layers. Resins such as polyimide, epoxy-based resin, acrylic-based resin, and so forth, can be used as the material making up the insulating layer.

The second interposer 20 does not have to include insulating layers situated on the third face 21 or the fourth face 22. For example, the second interposer 20 does not have to include insulating layers that are situated on the third face 21 or the fourth face 22 and that contain polyimide. That is to say, the surfaces of the substrate 201 do not have to be provided with insulating layers containing an organic insulating material. Accordingly, warping of the substrate 201 due to stress within the insulating layers can be suppressed. The substrate 201 of the second interposer 20 will also be referred to as second substrate 201.

The configurations of the substrate 101, the first through vias 14, the pads 16, the pillars 161, and the pads 17, of the first interposer 10 described above, can be employed as the configurations of the substrate 201, the second through vias 24, the pads 26, the pillars 261, and the pads 27, of the second interposer 20.

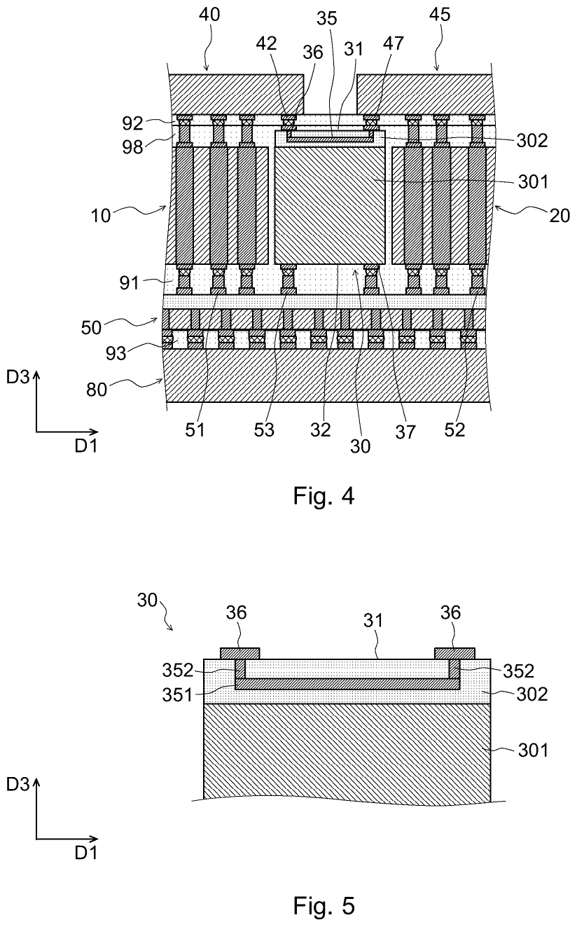

FIG. 4 is a sectional view illustrating the third interposer 30 in FIG. 2 in an enlarged manner. The third interposer 30 includes a substrate 301, an insulating layer 302 situated on the substrate 301, and wiring 35 that is in contact with the insulating layer 302. The insulating layer 302 may make up the fifth face 31. The insulating layer 302 and the wiring 35 may make up a so-called redistribution layer. An insulating layer may be provided on the substrate 302 on the sixth face 32 side as well, although not illustrated. In this case, the insulating layer may make up the sixth face 32. The third through vias 34 that are described above pass through the substrate 301. The substrate 301 of the third interposer 30 will also be referred to as third substrate 301.

As illustrated in FIG. 4, the third interposer 30 may include pads 36 situated on the fifth face 31. The third interposer 30 may include pads 37 situated on the sixth face 32.

The configurations of the substrate 101, the first through vias 14, the pads 16, and the pads 17, of the first interposer 10 described above can be employed as the configurations of the substrate 301, the third through vias 34, the pads 36, and the pads 37. Resins such as polyimide, epoxy-based resin, acrylic-based resin, and so forth, can be used as the material making up the insulating layer 302. The insulating layer 302 may contain a filler dispersed in resin such as an epoxy-based resin or the like. The filler is made of an inorganic material such as silica, alumina, or the like. The filler may be made of silicon oxide or silicon nitride. The silicon oxide or silicon nitride may contain fluorine or nitrogen.

Resins such as polyimide, epoxy-based resin, acrylic-based resin, and so forth, can be used as the material making up the insulating layer on the sixth face 32, and the insulating layers of the first interposer 10 and the second interposer 20. These insulating layers may also contain a filler dispersed in resin such as an epoxy-based resin or the like, in the same way as the insulating layer 302. The filler is made of, for example, silica, alumina, or the like. The filler may be made of silicon oxide or silicon nitride. The silicon oxide or silicon nitride may contain fluorine or nitrogen.

As illustrated in FIG. 4, the wiring 35 may include a first end that is connected to a first pad 36 and a second end that is connected to a second pad 36. FIG. 5 is a sectional view illustrating an example of the wiring 35. The wiring 35 may include a first portion 351 that extends in parallel with an in-plane direction of the fifth face 31, and second portions 352 extending in a direction including a component of the third direction D3. The second portions 352 may extend in parallel to the third direction D3. The second portions 352 may be connected to the pads 36. In this case, the second portions 352 make up the first end and the second end of the wiring 35.

The thickness of the first portion 351 is, for example, 0.5 μm or more, and may be 1.0 μm or more. The thickness of the pads 16 and 17 is, for example, 20.0 μm or less, and may be 5.0 μm or less. The materials listed with regard to the first through vias 14 may be used as the material making up the wiring 35.

The width of the first portion 351 is, for example, 0.1 μm or more, and may be 0.5 μm or more. The width of the first portion 351 is, for example, 20.0 μm or less, may be 10.0 μm or less, and may be 5.0 μm or less. The width of the first portion 351 is the dimension of the first portion 351 in a direction orthogonal to the direction in which the first portion 351 extends in plan view.

The degree of freedom in disposing the pads 36 can be raised by the third interposer 30 including the redistribution layer that includes the insulating layer 302 and the wiring 35.

In a case in which an insulating layer containing an organic insulating material such as resin or the like is provided on an inorganic substrate containing glass, silicon, or the like, warping of the substrate occurs due to stress within the insulating layer. The insulating layer 302 is situated on the fifth face 31 of the third interposer 30, but no insulating layer has to be situated on the first face 11 of the first interposer 10 or the third face 21 of the second interposer 20. Accordingly, the total amount of warping occurring in the interposer group can be reduced as compared to a case in which insulating layers are provided over the entire region of the interposer group including the first interposer 10, the second interposer 20, and the third interposer 30.

The first semiconductor element 40 includes transistors formed of semiconductors such as silicon and so forth. Examples of the first semiconductor element 40 include a CPU, a GPU, an FPGA, a sensor, memory, and so forth. The first semiconductor element 40 may also be chiplet to which one of functions of semiconductor element such as the CPU, the GPU, the FPGA, the sensor, the memory, and so forth, is assigned. The first semiconductor element 40 may include a plurality of substrates that are stacked.

The first semiconductor element 40 may include first pads 41 that are electrically connected to the first interposer 10. The first pads 41 may be electrically connected to the first through vias 14 via the pillars 161 and the pads 16, for example. Bumps may be provided between the first interposer 10 and the first pads 41.

The first semiconductor element 40 may include second pads 42 that are electrically connected to the third interposer 30. The second pads 42 may be electrically connected to the wiring 35 via the pads 36, for example. Bumps may be provided between the third interposer 30 and the second pads 42.

The second semiconductor element 45 includes transistors formed of semiconductors such as silicon and so forth. Examples of the second semiconductor element 45 include a CPU, a GPU, an FPGA, a sensor, memory, and so forth. The second semiconductor element 45 may also be chiplet to which one of functions of semiconductor element such as the CPU, the GPU, the FPGA, the sensor, the memory, and so forth, is assigned. The second semiconductor element 45 may include a plurality of substrates that are stacked.

The second semiconductor element 45 may include fourth pads 46 that are electrically connected to the second interposer 20. The fourth pads 46 may be electrically connected to the second through vias 24 via the pillars 261 and the pads 26, for example. Bumps may be provided between the second interposer 20 and the fourth pads 46.

The second semiconductor element 45 may include fifth pads 47 that are electrically connected to the third interposer 30. The fifth pads 47 may be electrically connected to the wiring 35 via the pads 36, for example. Bumps may be provided between the third interposer 30 and the fifth pads 47.

The third semiconductor element 50 includes transistors formed of semiconductors such as silicon and so forth. Examples of the third semiconductor element 50 include a CPU, a GPU, an FPGA, a sensor, memory, and so forth. The third semiconductor element 50 may also be chiplet to which one of functions of semiconductor element such as the CPU, the GPU, the FPGA, the sensor, the memory, and so forth, is assigned. The third semiconductor element 50 may include a substrate 56 and an insulating layer 57 that is situated on the substrate 56, as illustrated in FIG. 2. The third semiconductor element 50 may include electrodes 58 that pass through the substrate 56. Although not illustrated, the third semiconductor element 50 may include wiring situated in the insulating layer 57, electrodes that pass through the insulating layer 57, and so forth.

The third semiconductor element 50 may include eleventh pads 51 that are electrically connected to the first interposer 10. Pillars may be formed on the eleventh pads 51, and bumps may be formed on the pillars. The eleventh pads 51 may be electrically connected to the first through vias 14 via the pillars, the bumps, and the pads 17, for example.

The third semiconductor element 50 may include twelfth pads 52 that are electrically connected to the second interposer 20. Pillars may be formed on the twelfth pads 52, and bumps may be formed on the pillars. The twelfth pads 52 may be electrically connected to the second through vias 24 via the pillars, the bumps, and the pads 27, for example.

The third semiconductor element 50 may include thirteenth pads 53 that are electrically connected to the third interposer 30. Pillars may be formed on the thirteenth pads 53, and bumps may be formed on the pillars. The thirteenth pads 53 may be electrically connected to the pads 37 via the pillars and the bumps, for example.

The wiring substrate 80 includes a substrate 81 and pads 82 situated on the substrate 81. The pads 82 may be electrically connected to the third semiconductor element 50.

The substrate 81 may include a glass substrate, a quartz substrate, a sapphire substrate, a resin substrate, a silicon substrate, a silicon carbide substrate, an alumina (Al2O3) substrate, an aluminum nitride (AlN) substrate, a zirconia oxide (ZrO2) substrate, a lithium niobate substrate, a tantalum niobate substrate, or the like. The resin substrate may contain an organic material. For example, the resin substrate may contain epoxy resin, polyethylene, polypropylene, and so forth. The resin substrate may contain a filler dispersed in resin such as an epoxy-based resin or the like. The filler is made of, for example, silica, alumina, or the like. The resin substrate may include a plurality of layers of organic materials that are stacked. The thickness of the substrate 81 is, for example, 100 μm or more, may be 200 μm or more, and may be 500 μm or more. The thickness of the substrate 81 is, for example, 2 mm or less, may be 1.5 mm or less, and may be 1 mm or less.

The wiring substrate 80 may include the pads 82 that are electrically connected to the third semiconductor element 50. Pillars or bumps may be formed on the pads 82. In a case in which pillars are formed on the pads 82, bumps may be formed on the pillars. The pads 82 may be electrically connected to the third semiconductor element 50 via, for example, the pillars and the bumps.

The semiconductor package 1 may include an underfill 91 that is situated between the first interposer 10, second interposer 20, or third interposer 30, and the third semiconductor element 50. The underfill 91 may contain a thermosetting resin such as an epoxy-based resin or the like. The underfill 91 can function as an adhesive agent that joins the first interposer 10, the second interposer 20, or the third interposer 30, and the third semiconductor element 50.

The semiconductor package 1 may include a mold 98 that covers the first interposer 10, the second interposer 20, and the third interposer 30. The mold 98 may be situated between the first interposer 10 and the third interposer 30, and between the second interposer 20 and the third interposer 30. The mold 98 may contain a thermosetting resin such as an epoxy-based resin or the like.

The semiconductor package 1 may include an underfill 92 that is situated between the first semiconductor element 40 or second semiconductor element 45, and the first interposer 10, second interposer 20, or third interposer 30. The underfill 92 may contain a thermosetting resin such as an epoxy-based resin or the like. The underfill 92 can function as an adhesive agent that joins the first semiconductor element 40 or the second semiconductor element 45, and the first interposer 10 and the second interposer 20 or the third interposer 30.

The semiconductor package 1 may include an underfill 93 that is situated between the third semiconductor element 50 and the wiring substrate 80. The underfill 93 may contain a thermosetting resin such as an epoxy-based resin or the like. The underfill 93 can function as an adhesive agent that joins the third semiconductor element 50 and the wiring substrate 80.

Next, operations of the semiconductor package 1 according to the present embodiment will be described.

When the temperature of the semiconductor package 1 changes, expansion or contraction occurs in the components of the semiconductor package 1. For example, when the temperature of the semiconductor package 1 rises, expansion occurs in accordance with the coefficient of thermal expansion of the components of the semiconductor package 1. When the temperature of the semiconductor package 1 falls, contraction occurs in accordance with the coefficient of thermal expansion of the components of the semiconductor package 1. Generally speaking, the coefficient of thermal expansion of inorganic materials is small as compared to the coefficient of thermal expansion of organic materials. For example, the coefficients of thermal expansion of the inorganic materials making up the substrates 101, 201, and 301 are smaller than the coefficients of thermal expansion of the organic materials making up the insulating layers. In this case, when the temperature of the semiconductor package 1 changes, warping occurs at the substrates 101, 201, and 301 of the interposers 10, 20, and 30, due to difference in the coefficients of thermal expansion of the components.

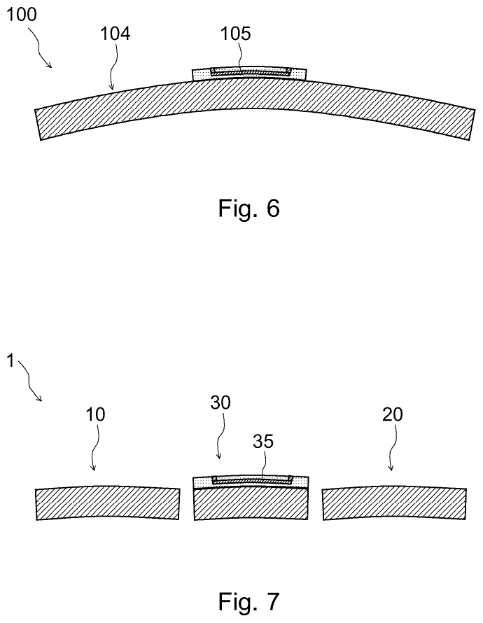

FIG. 6 is a diagram schematically illustrating warping occurring in a semiconductor package 100 according to a comparative embodiment. The semiconductor package 100 includes one interposer 104, and a first semiconductor element and a second semiconductor element that are not illustrated, which are mounted on the interposer 104. The interposer 104 includes wiring 105 that electrically connects the first semiconductor element and the second semiconductor element.

In the comparative embodiment in FIG. 6, warping occurs in the interposer 104 in accordance with temperature change of the semiconductor package 100. In this case, stress that occurs due to warping of the one interposer 104 is applied to the wiring 105.

FIG. 7 is a diagram schematically illustrating warping occurring in the semiconductor package 1 according to the present embodiment. As described above, the semiconductor package 1 includes the first interposer 10, the second interposer 20, and the third interposer 30. Also, the semiconductor package 1 includes the first semiconductor element 40 that is not illustrated, which is mounted on the first interposer 10 and the third interposer 30, and the second semiconductor element 45 that is not illustrated, which is mounted on the second interposer 20 and the third interposer 30.

In the present embodiment, the dimensions of the first interposer 10, the second interposer 20, and the third interposer 30 are small in comparison with the dimensions of the interposer 104 according to the comparative example. Thus, the curvature of warping occurring in the first interposer 10, the second interposer 20, and the third interposer 30 can be made to be smaller than the curvature of warping occurring in the interposer 104. Thus, the stress occurring due to the warping of the third interposer 30 can be reduced. Hence, the stress applied to the wiring 35 is smaller, and accordingly damage occurring in the wiring 35 can be suppressed. Thus, reliability of the semiconductor package 1 can be improved. An example of damage occurring in the wiring 35 is line breakage, for example, occurring at boundaries between the first portion 351 and the second portions 352 in FIG. 5.

Next, a manufacturing method of the semiconductor package 1 will be described.

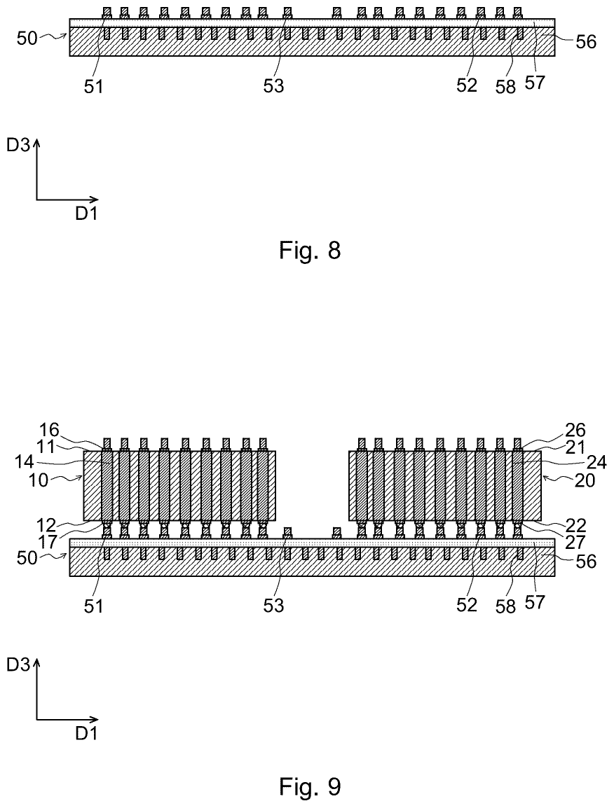

First, as illustrated in FIG. 8, a preparation step of preparing the third semiconductor element 50 is carried out. The substrate 56 may be a silicon wafer, for example. The electrodes 58 may include end portions that are not exposed to the surface of the substrate 56.

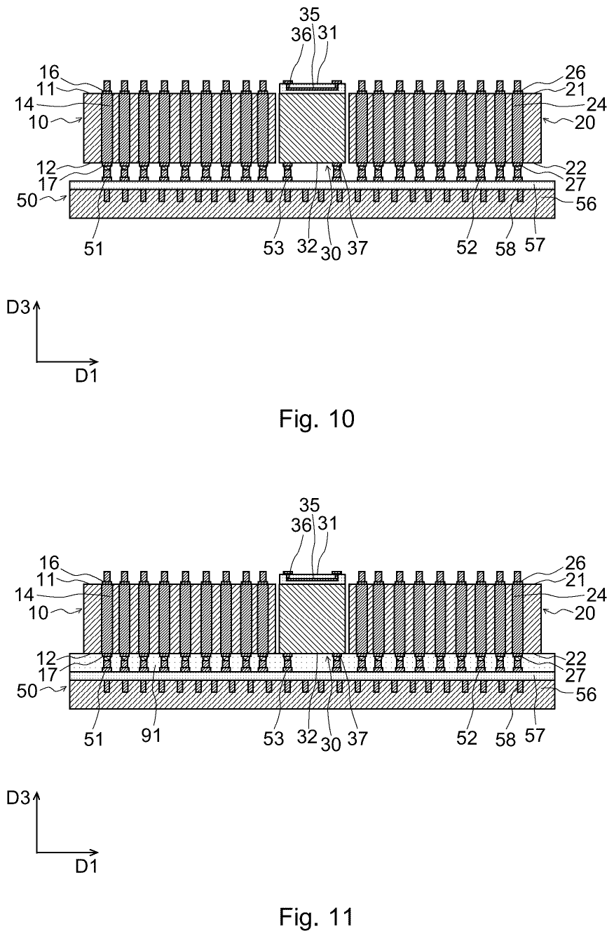

Subsequently, a disposing step of disposing the first interposer 10, the second interposer 20, and the third interposer 30 on the third semiconductor element 50 is carried out. For example, as illustrated in FIG. 9, the first interposer 10 and the second interposer 20 are disposed on the third semiconductor element 50. Subsequently, as illustrated in FIG. 10, the third interposer 30 is disposed between the first interposer 10 and the second interposer 20, on the third semiconductor element 50. The disposing step is carried out such that the second face 12, the fourth face 22, and the sixth face 32 overlap the third semiconductor element 50 in plan view.

A plurality of sets may be disposed on the third semiconductor element 50 in the disposing step. One set includes one first interposer 10, one second interposer 20, and one third interposer 30.

Subsequently, as illustrated in FIG. 11, space between the first interposer 10, second interposer 20, and third interposer 30, and the third semiconductor element 50, may be filled with the underfill 91.

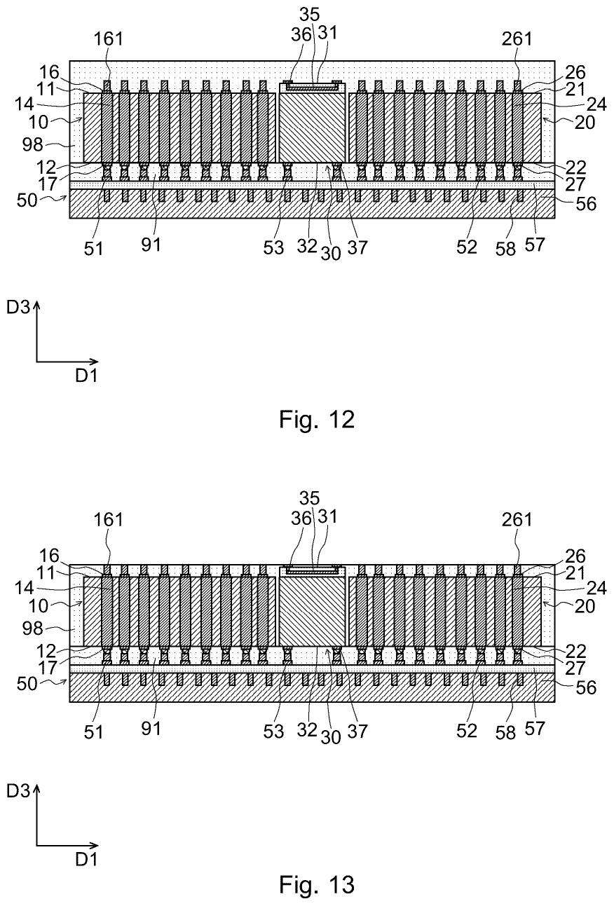

Subsequently, as illustrated in FIG. 12, the mold 98 may be formed so as to cover the first interposer 10, the second interposer 20, and the third interposer 30. At this time, the first interposer 10, the second interposer 20, and the third interposer 30 do not have to be exposed to the surface of the mold 98. In this case, a step of grinding the mold 98 such that the components of the interposers 10, 20, and 30, such as the pillars 161, the pillars 261, the pads 36, and so forth, for example, are exposed to the surface of the mold 98, as illustrated in FIG. 13, may be carried out.

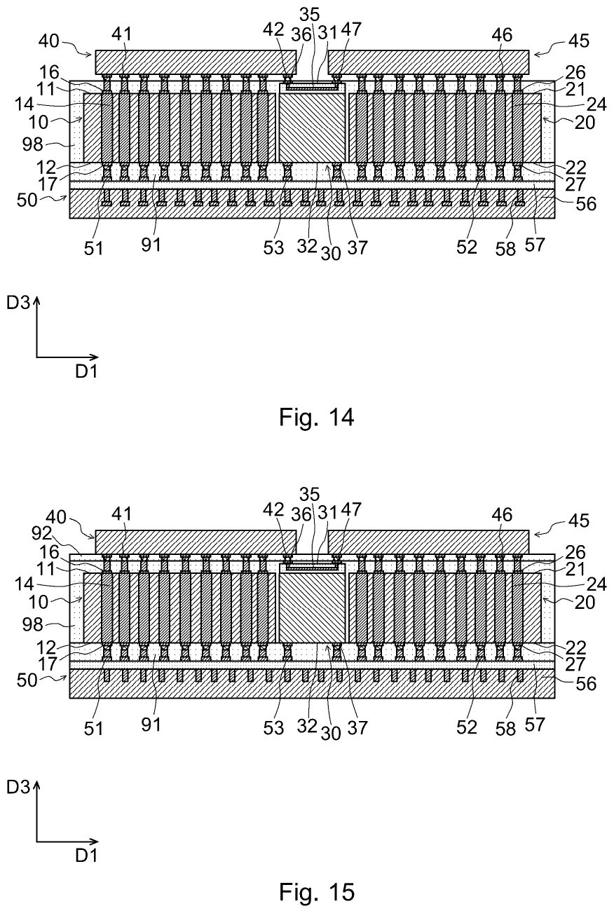

Subsequently, as illustrated in FIG. 14, a first mounting step of mounting the first semiconductor element 40 on the first interposer 10 and the third interposer 30 is carried out. The first mounting step is carried out such that the first semiconductor element 40 overlaps the first face 11 and the fifth face 31 in plan view. Also, a second mounting step of mounting the second semiconductor element 45 on the second interposer 20 and the third interposer 30 is carried out. The second mounting step is carried out such that the second semiconductor element 45 overlaps the third face 21 and the fifth face 31 in plan view.

Subsequently, as illustrated in FIG. 15, space between the first semiconductor element 40 and second semiconductor element 45, and the first interposer 10, second interposer 20, and third interposer 30, may be filled with the underfill 92.

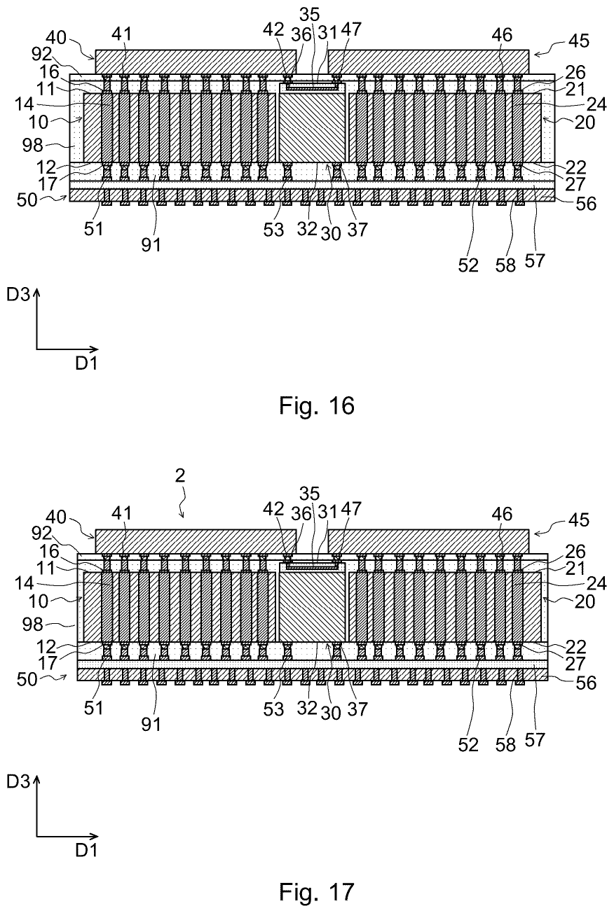

Subsequently, as illustrated in FIG. 16, a step of grinding the substrate 56 such that the electrodes 58 are exposed to the surface of the substrate 56 may be carried out. Thereafter, pads may be formed on the electrodes 58.

In a case in which the substrate 56 of the third semiconductor element 50 is a silicon wafer, a dicing step may be carried out to cut the substrate 56 into a plurality of pieces, as illustrated in FIG. 17. In the dicing step, the substrate 56 is cut such that one above-described set is situated on one piece of the substrate 56, for example. A structure including one piece of the substrate 56 and one above-described set will also be referred to as a chip 2.

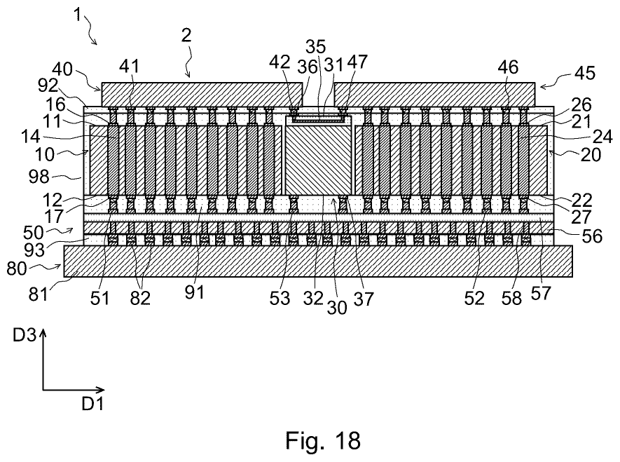

Subsequently, as illustrated in FIG. 18, the wiring substrate 80 is prepared. Thereafter, the chip 2 is mounted on the wiring substrate 80. Thus, the semiconductor package 1 is manufactured.

According to the present embodiment, one chip 2 includes a plurality of interposers 10, 20, and 30 that are separated from each other. Accordingly, the curvature of warping that occurs in the interposers can be reduced as compared to a case in which only one interposer is included in one chip, as in the comparative embodiment. Thus, defects such as line breakage and so forth occurring in wiring that electrically connects two semiconductor elements included in one chip 2 can be suppressed.

The embodiment described above can be modified variously. Other embodiments will be described below with reference to drawings as necessary. In the following description and the drawings used in the following description, portions that can be configured in the same way as in the embodiment described above will be denoted by the same signs as the signs used for the corresponding portions in the embodiment described above, and repetitive description will be omitted. Also, in cases in which it is clear that advantageous effects obtained in the embodiment described above will be obtained in the other embodiments as well, description thereof may be omitted.

### Second Embodiment

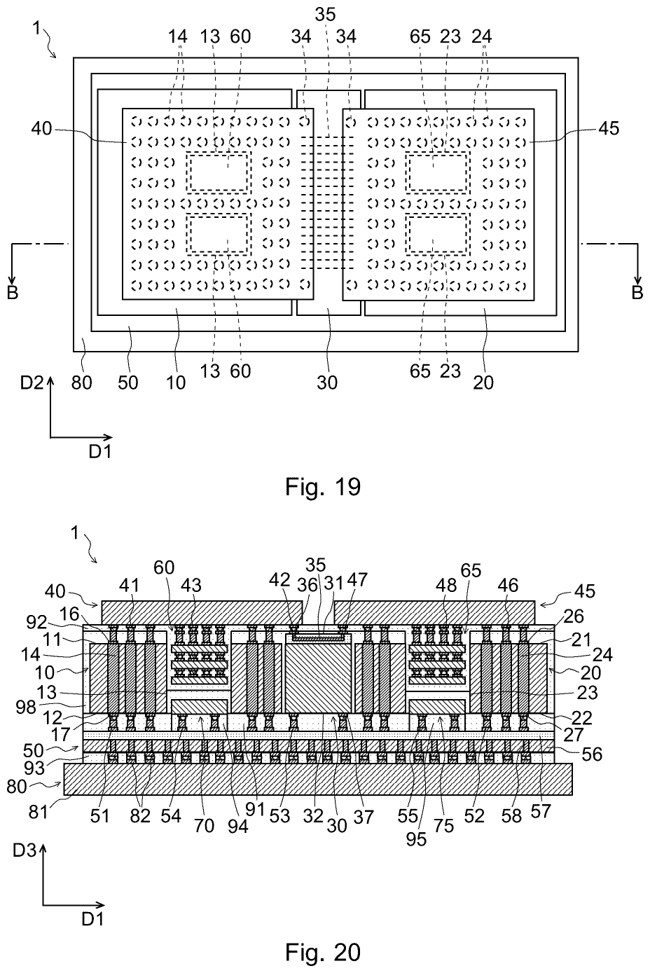

FIG. 19 is a plan view illustrating a semiconductor package 1 according to a second embodiment. FIG. 20 is a sectional view taken along line B-B of the semiconductor package 1 in FIG. 19.

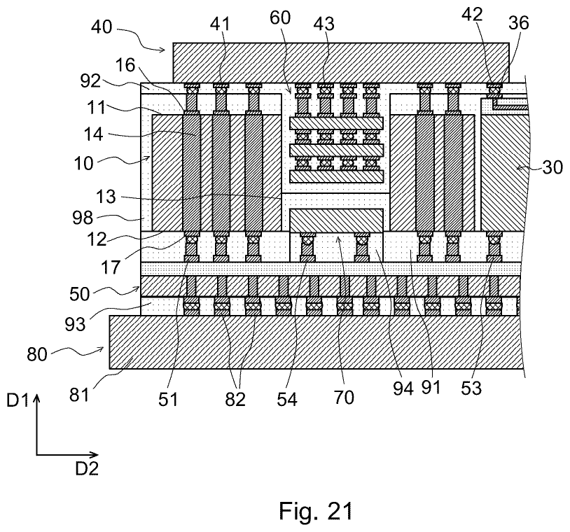

As illustrated in FIG. 19 and FIG. 20, the first interposer 10 may include first cavities 13 situated in the first face 11. FIG. 21 is a sectional view illustrating the first interposer 10 in FIG. 20 in an enlarged manner.

The first cavities 13 are recessed portions formed in the first face 11. In this case, the semiconductor package 1 may include semiconductor elements 60 situated in the first cavities 13. The semiconductor elements 60 are electrically connected to the first semiconductor element 40. For example, the first semiconductor element 40 may include third pads 43 electrically connected to the semiconductor elements 60. In the following description, the semiconductor elements 60 situated within the first cavities 13 will also be referred to as first internal semiconductor elements 60.

Examples of the first internal semiconductor elements 60 include CPUs, GPUs, FPGAs, sensors, memory, and so forth. In a case in which the first semiconductor element 40 includes a processing circuit such as a CPU, a GPU, an FPGA, or the like, the first internal semiconductor elements 60 may include memory used by the processing circuit of the first semiconductor element 40. Examples of the memory include SRAM, DRAM, and so forth.

As illustrated in FIG. 20 and FIG. 21, the first cavities 13 may pass through from the first face 11 to the second face 12. In this case, the semiconductor package 1 may include elements 70 situated in the first cavities 13. The elements 70 are electrically connected to the third semiconductor element 50. For example, the third semiconductor element 50 may include fourteenth pads 54 electrically connected to the elements 70. In the following description, the elements 70 situated in the cavities are also referred to as first internal elements 70.

The first internal elements 70 may be active elements or may be passive elements. Examples of active elements include CPUs, GPUs, FPGAs, sensors, memory, and so forth. Examples of passive elements include capacitors, resistors, inductors, and so forth. In a case in which the third semiconductor element 50 includes a processing circuit such as a CPU, a GPU, an FPGA, or the like, the first internal elements 70 may include passive elements electrically connected to the processing circuit of the third semiconductor element 50.

As illustrated in FIG. 19 and FIG. 20, the second interposer 20 may include second cavities 23 situated in the third face 21. The second cavities 23 are recessed portions formed in the third face 21, in the same way as the first cavities 13. In this case, the semiconductor package 1 may include second semiconductor elements 65 situated in the second cavities 23. The second semiconductor elements 65 are electrically connected to the second semiconductor element 45. For example, the second semiconductor element 45 may include sixth pads 48 electrically connected to the second semiconductor elements 65.

As illustrated in FIG. 20, the second cavities 23 may pass through from the third face 21 to the fourth face 22. In this case, the semiconductor package 1 may include second internal elements 75 situated in the second cavities 23. The second internal elements 75 are electrically connected to the third semiconductor element 50. For example, the third semiconductor element 50 may include fifteenth pads 55 electrically connected to the second internal elements 75.

The configurations of the first internal semiconductor elements 60 and the first internal elements 70 described above can be employed as the configurations of the second internal semiconductor elements 65 and the second internal elements 75.

Next, a manufacturing method of the semiconductor package 1 will be described.

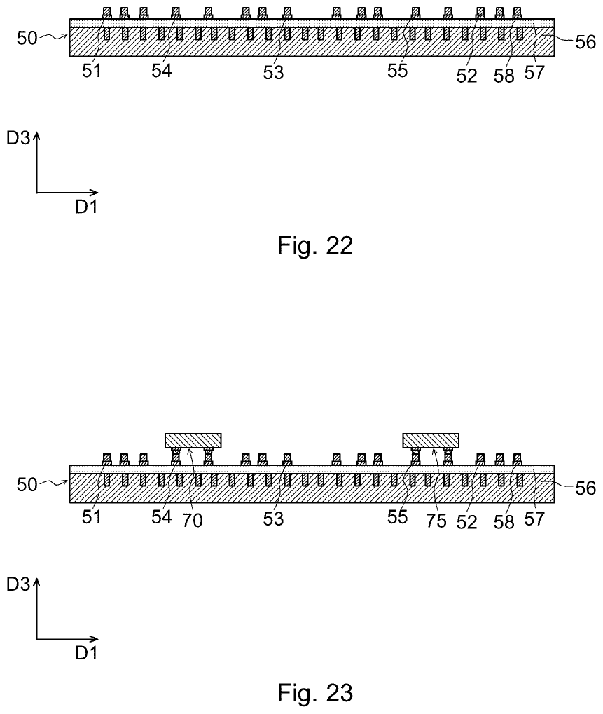

First, as illustrated in FIG. 22, a preparation step of preparing the third semiconductor element 50 is carried out. The substrate 56 may be a silicon wafer, for example. The electrodes 58 may include end portions that are not exposed to the surface of the substrate 56.

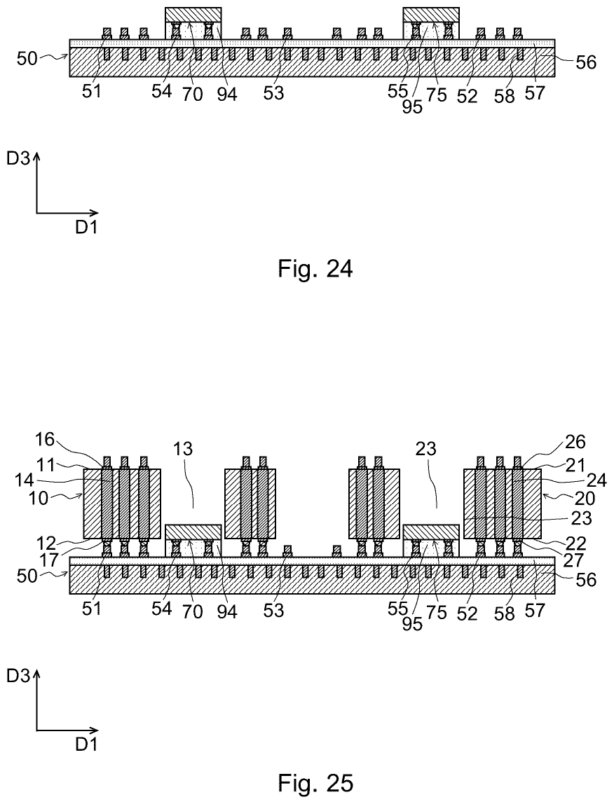

Subsequently, as illustrated in FIG. 23, the first internal elements 70 and the second internal elements 75 are disposed on the third semiconductor element 50. Subsequently, as illustrated in FIG. 24, space between the first internal elements 70 and the second internal elements 75, and the third semiconductor element 50, may be filled with underfill 94, 95.

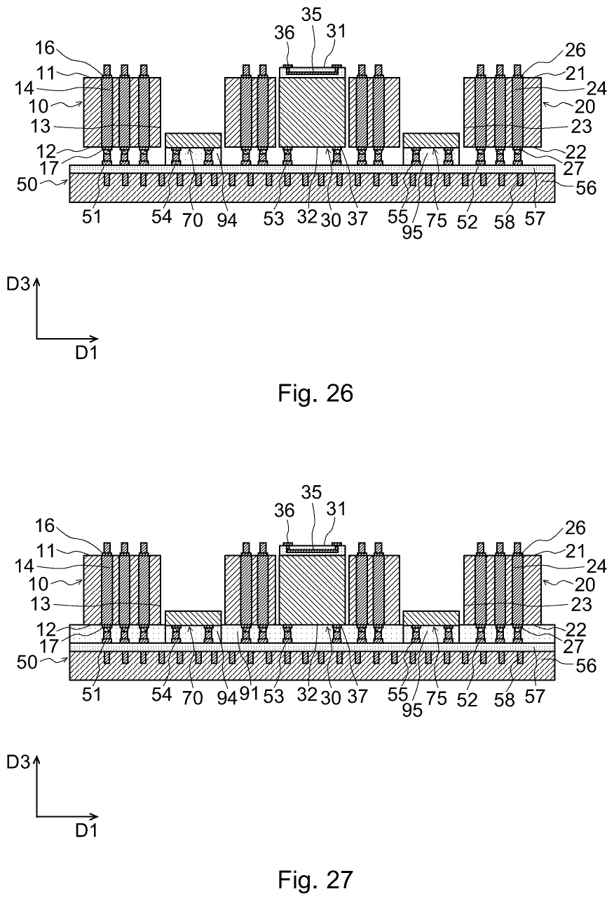

Subsequently, a disposing step of disposing the first interposer 10, the second interposer 20, and the third interposer 30 on the third semiconductor element 50 is carried out. For example, as illustrated in FIG. 25, the first interposer 10 and the second interposer 20 are disposed on the third semiconductor element 50. At this time, the disposing step is carried out such that the first internal elements 70 are situated in the first cavities 13 of the first interposer 10, and the second internal elements 75 are situated in the second cavities 23 of the second interposer 20. Subsequently, as illustrated in FIG. 26, the third interposer 30 is disposed on the third semiconductor element 50 between the first interposer 10 and the second interposer 20.

A plurality of sets may be disposed on the third semiconductor element 50 in the disposing step. One set may include one first interposer 10, one second interposer 20, and one third interposer 30.

Subsequently, as illustrated in FIG. 27, space between the first interposer 10, second interposer 20, and third interposer 30, and the third semiconductor element 50, may be filled with the underfill 91.

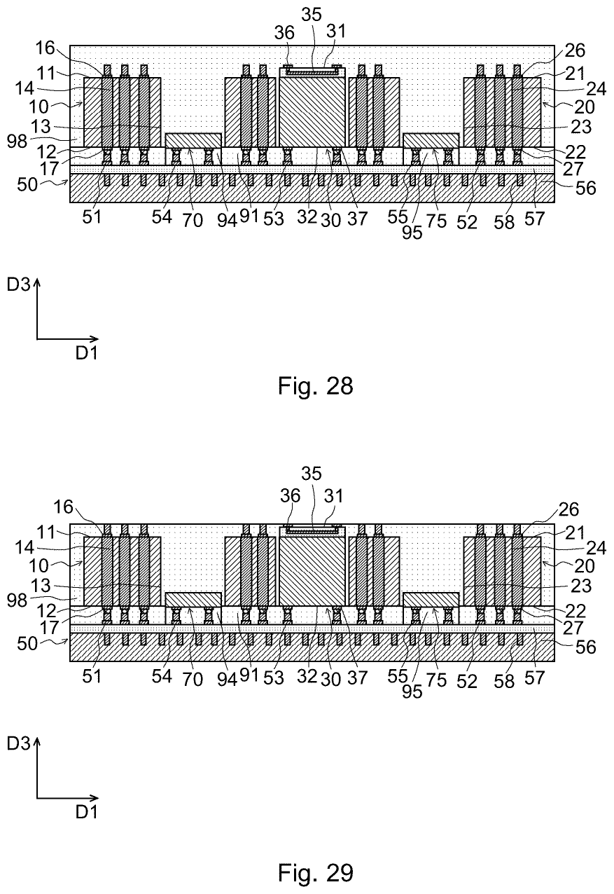

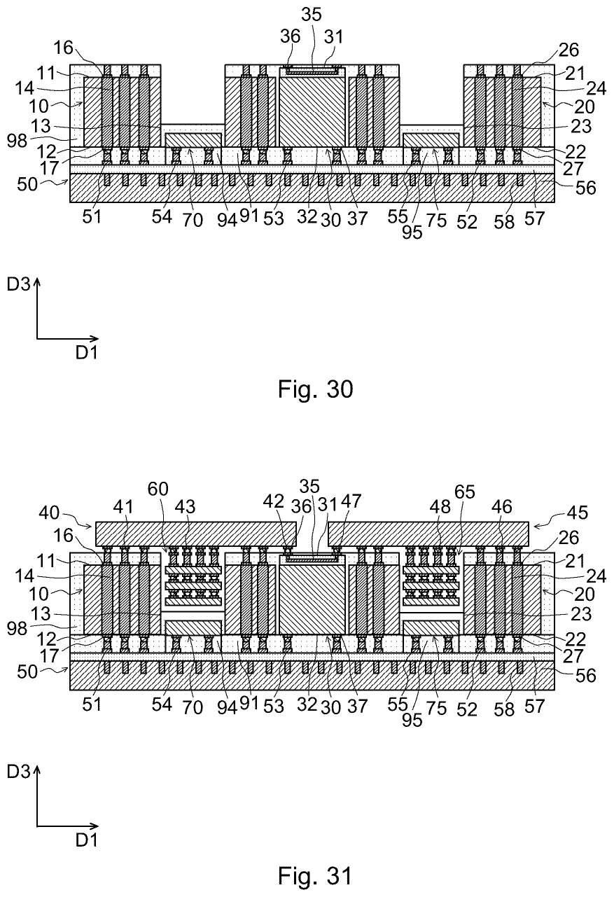

Subsequently, as illustrated in FIG. 28, the mold 98 may be formed so as to cover the first interposer 10, the second interposer 20, and the third interposer 30. At this time, the first interposer 10, the second interposer 20, and the third interposer 30 do not have to be exposed to the surface of the mold 98. In this case, a step of grinding the mold 98 such that the components of the interposers 10, 20, and 30, such as the pillars 161, the pillars 261, the pads 36, and so forth, for example, are exposed to the surface of the mold 98, as illustrated in FIG. 29, may be carried out. Subsequently, a step of removing the mold 98 situated in the first cavities 13 and the second cavities 23 is carried out, as illustrated in FIG. 30.

Subsequently, as illustrated in FIG. 31, a first mounting step of mounting the first semiconductor element 40 on the first interposer 10 and the third interposer 30 is carried out. The first mounting step is carried out such that the first semiconductor element 40 overlaps the first face 11 and the fifth face 31 in plan view. Also, a second mounting step of mounting the second semiconductor element 45 on the second interposer 20 and the third interposer 30 is carried out. The second mounting step is carried out such that the second semiconductor element 45 overlaps the third face 21 and the fifth face 31 in plan view.

As illustrated in FIG. 31, the first internal semiconductor elements 60 may be mounted on the first semiconductor element 40 in advance. In this case, the first mounting step is carried out such that the first internal semiconductor elements 60 are disposed in the first cavities 13.

In the same way, the second internal semiconductor elements 65 may be mounted on the second semiconductor element 45 in advance. In this case, the second mounting step is carried out such that the second internal semiconductor elements 65 are disposed in the second cavities 23.

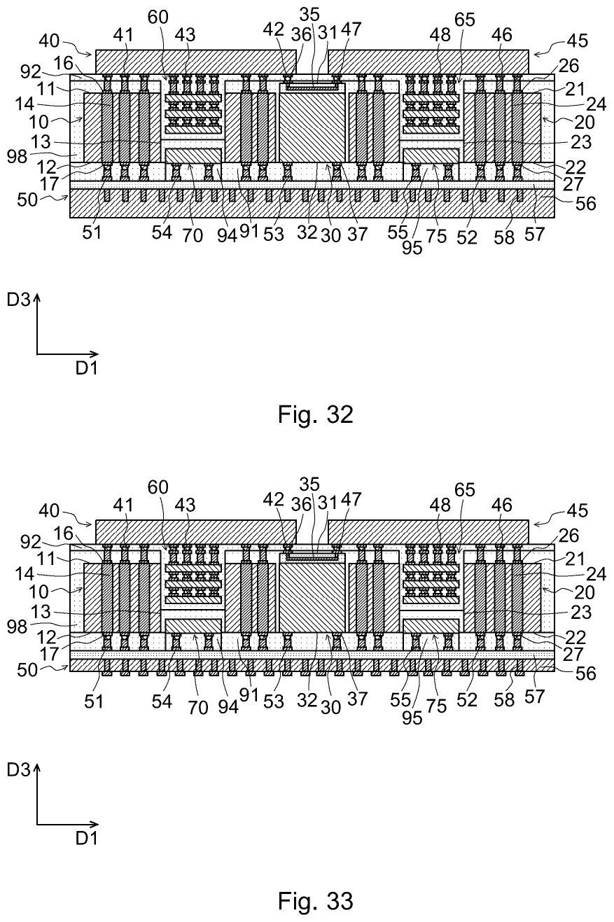

Subsequently, as illustrated in FIG. 32, space between the first semiconductor element 40 and second semiconductor element 45, and the first interposer 10, second interposer 20, and third interposer 30, may be filled with the underfill 92.

Subsequently, as illustrated in FIG. 33, a step of grinding the substrate 56 such that the electrodes 58 are exposed to the surface of the substrate 56 may be carried out. Thereafter, pads may be formed on the electrodes 58.

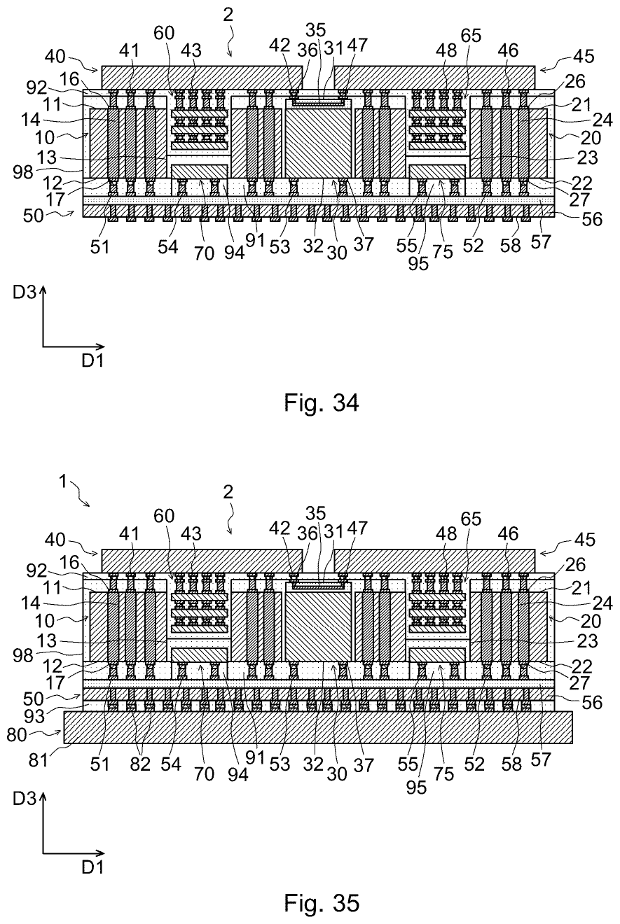

In a case in which the substrate 56 of the third semiconductor element 50 is a silicon wafer, a dicing step may be carried out to cut the substrate 56 into a plurality of pieces, as illustrated in FIG. 34. Thus, a plurality of chips 2 can be obtained.

Subsequently, as illustrated in FIG. 35, the wiring substrate 80 is prepared. Thereafter, the chip 2 is mounted on the wiring substrate 80. Thus, the semiconductor package 1 is manufactured.

According to the present embodiment, providing the first cavities 13 in the first interposer 10 enables the first internal semiconductor elements 60 to be disposed in the first cavities 13. Accordingly, the distance between the first semiconductor element 40 and the first internal semiconductor elements 60 can be reduced on one face of the first semiconductor element 40. A heat sink or the like, which is not illustrated, may be disposed on the other face of the first semiconductor element 40. In the same way, according to the present embodiment, the second internal semiconductor elements 65 can be disposed in the second cavities 23. Accordingly, the distance between the third semiconductor element 50 and the second internal semiconductor elements 65 can be reduced on one face of the second semiconductor element 45.

According to the present embodiment, providing the first cavities 13 in the first interposer 10 enables the first internal elements 70 to be disposed in the first cavities 13. Accordingly, the distance between the third semiconductor element 50 and the first internal elements 70 can be reduced on one face of the third semiconductor element 50. In the same way, according to the present embodiment, the second internal elements 75 can be disposed in the second cavities 23. Accordingly, the distance between the third semiconductor element 50 and the second internal elements 75 can be reduced on one face of the third semiconductor element 50.

### Third Embodiment

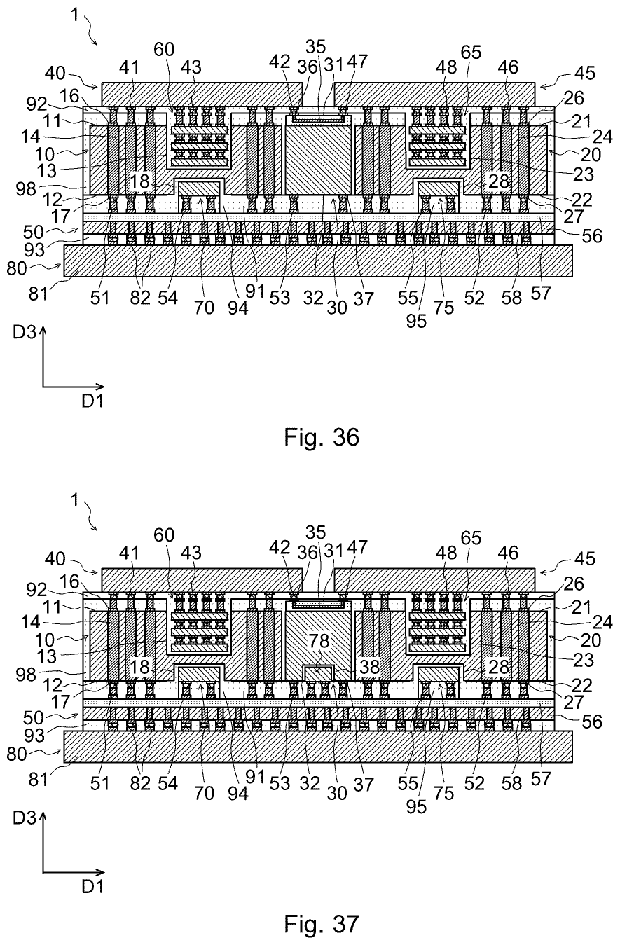

FIG. 36 is a sectional view illustrating a semiconductor package 1 according to a third embodiment. As illustrated in FIG. 36, the first cavities 13 of the first interposer 10 do not have to pass through from the first face 11 to the second face 12. In this case, cavities 18 that are not connected to the first cavities 13 may be formed in the second face 12. The first internal elements 70 may be situated in the cavities 18.

In the same way, the second cavities 23 of the second interposer 20 do not have to pass through from the third face 21 to the fourth face 22. In this case, cavities 28 that are not connected to the second cavities 23 may be formed in the fourth face 22. The second internal elements 75 may be situated in the cavities 28.

### Fourth Embodiment

FIG. 37 is a sectional view illustrating a semiconductor package 1 according to a fourth embodiment. As illustrated in FIG. 37, a cavity(ies) 38 may be formed in the sixth face 32 of the third interposer 30. In this case, the semiconductor package 1 may include a third internal element 78 situated in the cavity 38. The third internal element 78 may be electrically connected to the third semiconductor element 50. For example, the third semiconductor element 50 may include pads that are electrically connected to the third internal element 78.

The configuration of the first internal elements 70 described above can be employed as the configuration of the third internal elements 78.

Cavities may be formed in the fifth face 31 of the third interposer 30, although not illustrated. In this case, the semiconductor package 1 may include third internal semiconductor elements situated in the cavities of the fifth face 31. The third internal semiconductor elements may be electrically connected to the first semiconductor element 40 or the second semiconductor element 45.

### Fifth Embodiment

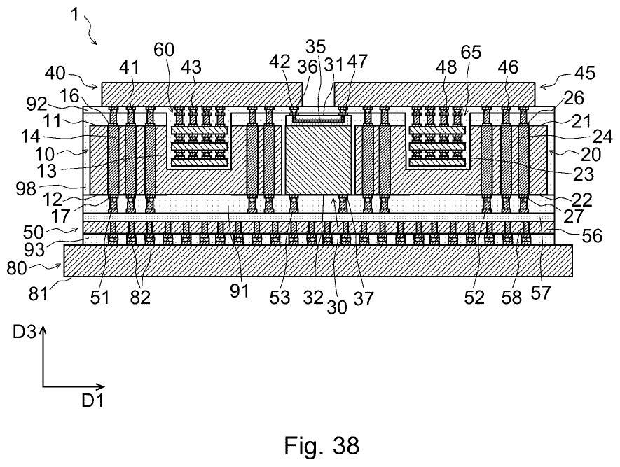

FIG. 38 is a sectional view illustrating a semiconductor package 1 according to a fifth embodiment. As illustrated in FIG. 38, the first cavities 13 of the first interposer 10 do not have to pass through from the first face 11 to the second face 12. Cavities do not have to be formed in the second face 12. In this case, the semiconductor package 1 does not have to include first internal elements.

In the same way, the second cavities 23 of the second interposer 20 do not have to pass through from the third face 21 to the fourth face 22. Cavities do not have to be formed in the fourth face 22. In this case, the semiconductor package 1 does not have to include second internal elements.

### Other Embodiments

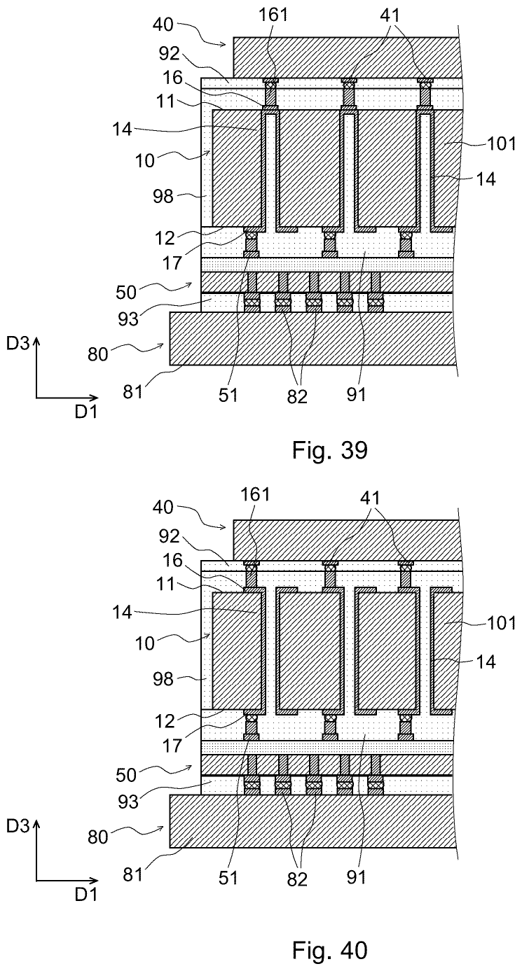

An example in which the first through vias 14 are situated over the entire region of the through holes of the substrate 101 is described in the above embodiment. That is to say, an example in which the first through vias 14 are filled vias is described. However, any structure may be employed for the first through vias 14, as long as the structure extends from one face of the substrate 101 to the other face thereof. For example, as illustrated in FIG. 39 and FIG. 40, the first through vias 14 do not have to fill the through holes to the centers thereof. In this case, a material that differs from the material of the first through vias 14 may be used to fill the inner sides of the first through vias 14. That is to say, the first interposer 10 may include portions situated on the inner side of the first through vias 14 and filled with an inorganic material, an organic material, or a conductive material. Examples of the inorganic material include an inorganic oxide, such as silica, alumina, or the like. The inner sides of the first through vias 14 may be filled with an organic material, and a filler of an inorganic material. Examples of the conductive material include metal such as copper, gold, nickel, and so forth. The inner sides of the first through vias 14 may be filled with a material in a paste form containing particles of a conductive material and a binder.

As illustrated in FIG. 39, the first through vias 14 may include a conductive layer covering the through holes along the first face 11. In this case, the pads 16 and pillars may be situated on the conductive layer covering the through holes. Although not illustrated, the first through vias 14 may include a conductive layer covering the through holes along the second face 12. This conductive layer may make up wiring situated on the second face 12. The pads 17 and pillars may be situated on the conductive layer covering the through holes along the second face 12.

Alternatively, as illustrated in FIG. 40, the first through vias 14 do not have to include a conductive layer covering the through holes along the first face 11 or the second face 12. In this case, the first through vias 14 may be connected to the pads 16 situated on the first face 11 and the pads 17 situated on the second face 12.

Although not illustrated, the second through vias 24 do not have to fill the through holes to the centers thereof either, the same as the first through vias 14. In this case, the second through vias 24 may include a conductive layer covering the through holes along the third face 21, the same as the first through vias 14 in FIG. 39. In this case, the pads 26 and pillars may be situated on the conductive layer covering the through holes. Although not illustrated, the second through vias 24 may include a conductive layer covering the through holes along the fourth face 22. The pads 27 and pillars may be situated on the conductive layer covering the through holes along the fourth face 22.

Alternatively, the second through vias 24 do not have to include a conductive layer covering the through holes along the third face 21 or the fourth face 22, in the same way as the first through vias 14 in FIG. 40.

(Example of Products in which Semiconductor Package is Mounted)

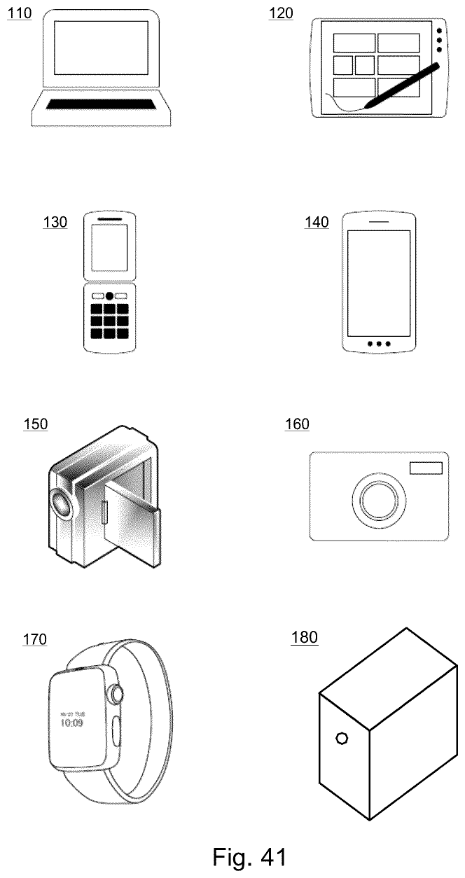

FIG. 41 is a diagram illustrating an example of products in which the semiconductor package 1 is mounted. The semiconductor package 1 can be used in various products. For example, the semiconductor package 1 is mounted in laptop personal computers 110, tablet terminals 120, mobile phones 130, smartphones 140, digital video cameras 150, digital cameras 160, digital timepieces 170, servers 180, and so forth.

### Sixth Embodiment

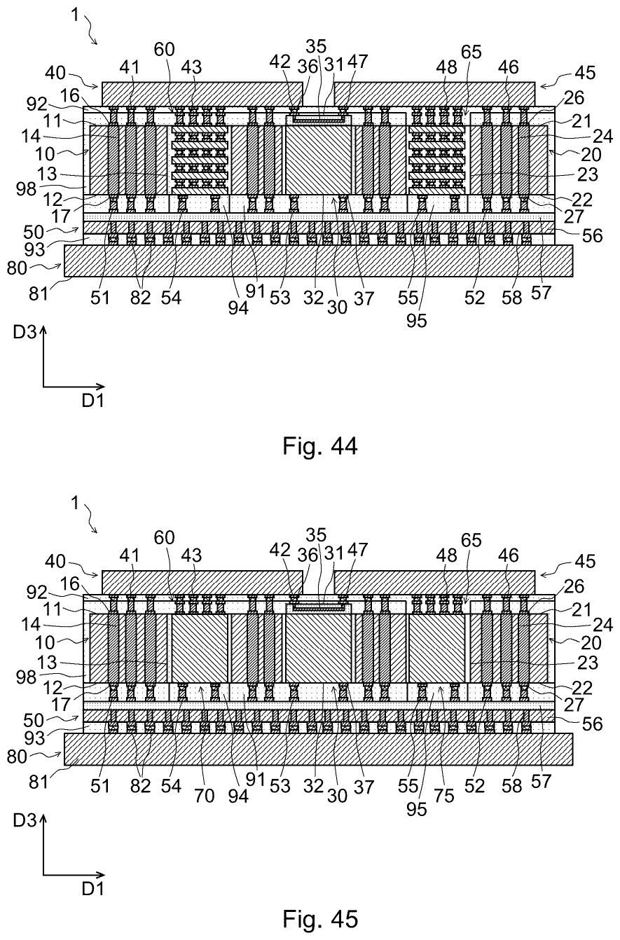

FIG. 44 and FIG. 45 are each a sectional view illustrating a semiconductor package 1 according to a sixth embodiment. The first internal semiconductor elements 60 situated in the first cavities 13 may be electrically connected to the third semiconductor element 50. As illustrated in FIG. 44, the first internal semiconductor elements 60 may include a plurality of insulating layers and conductive layers that are stacked. As illustrated in FIG. 45, the first internal semiconductor elements 60 may be semiconductor packages that are sealed by a mold resin or the like.

In the same way as the first internal semiconductor elements 60, the second internal semiconductor elements 65 situated in the second cavities 23 may be electrically connected to the third semiconductor element 50. As illustrated in FIG. 44, the second internal semiconductor elements 65 may include a plurality of insulating layers and conductive layers that are stacked. As illustrated in FIG. 45, the second internal semiconductor elements 65 may be semiconductor packages that are sealed by a mold resin or the like.

### Seventh Embodiment

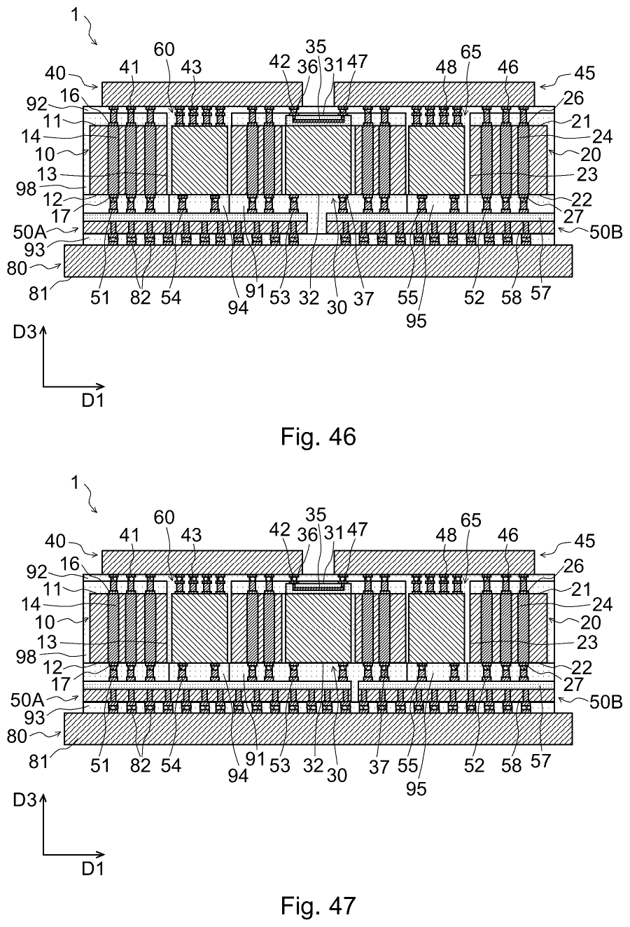

FIG. 46 and FIG. 47 are each a sectional view illustrating a semiconductor package 1 according to a seventh embodiment. The third semiconductor element 50 may include a plurality of semiconductor elements 50A and 50B. That is to say, the third semiconductor element 50 may be divided into the plurality of semiconductor elements 50A and 50B.

The position at which the third semiconductor element 50 is divided is not limited in particular.

For example, as illustrated in FIG. 46, the semiconductor element 50A may be electrically connected to the first interposer 10 and the third interposer 30, and the semiconductor element 50B may be electrically connected to the second interposer 20 and the third interposer 30.

For example, as illustrated in FIG. 47, the semiconductor element 50A may be electrically connected to the first interposer 10 and the third interposer 30, and the semiconductor element 50B may be electrically connected to the second interposer 20. The semiconductor element 50B does not have to be electrically connected to the third interposer 30. For example, the semiconductor element 50B does not have to overlap the third interposer 30 in plan view.

### Eighth Embodiment

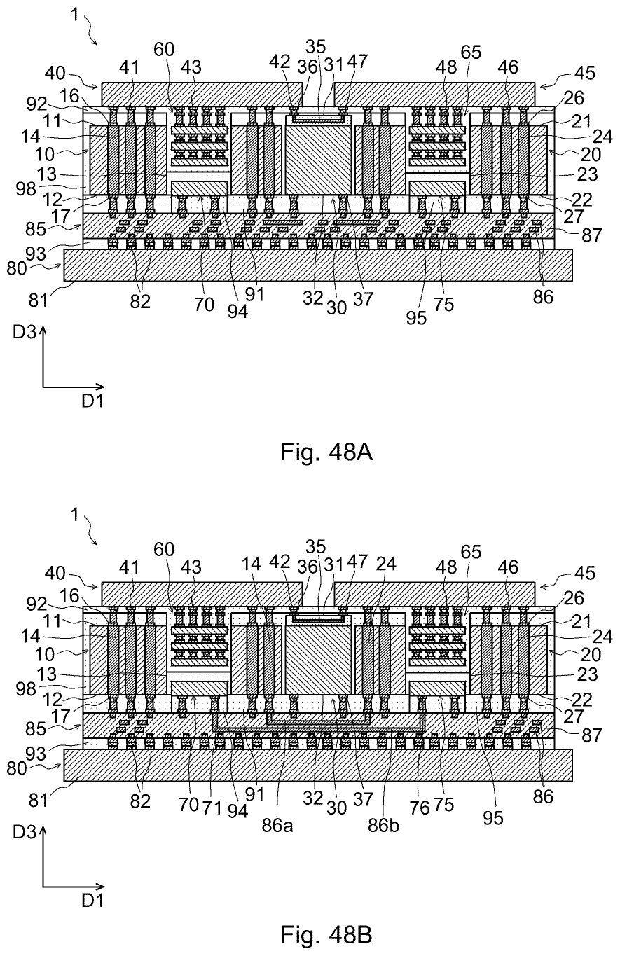

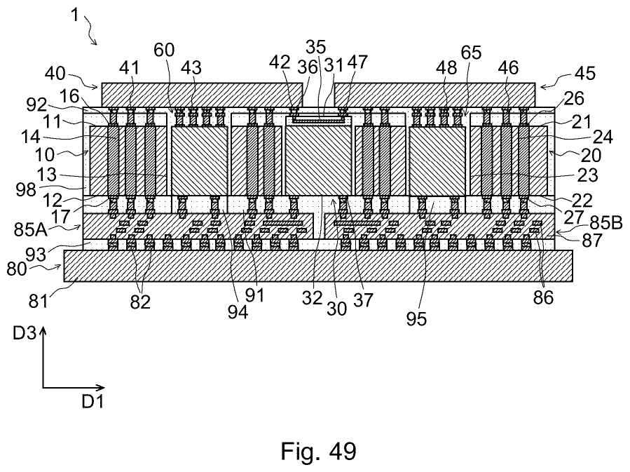

FIG. 48A, FIG. 48B, and FIG. 49 are each a sectional view illustrating a semiconductor package 1 according to an eighth embodiment. The semiconductor package 1 may include a redistribution layer 85 including a conductive layer 86 and an insulating layer 87. The redistribution layer 85 may face the second face 12 of the first interposer 10, the fourth face 22 of the second interposer 20, and the sixth face 32 of the third interposer 30. The conductive layer 86 of the redistribution layer 85 may be electrically connected to the first interposer 10, the second interposer 20, and the third interposer 30.

Metals such as copper, gold, silver, platinum, rhodium, tin, aluminum, nickel, chromium or the like, or alloys using these, may be used as the material making up the conductive layer 86. Organic insulating materials such as polyimide, epoxy-based resin, acrylic-based resin, and so forth, can be used as the material making up the insulating layer 87.

The redistribution layer 85 may be provided instead of the third semiconductor element 50. For example, the first interposer 10, the second interposer 20, and the third interposer 30 may be mounted on the redistribution layer 85. The redistribution layer 85 may be electrically connected to the wiring substrate 80.

As illustrated in FIG. 48A and FIG. 48B, one redistribution layer 85 may overlap the first interposer 10, the second interposer 20, and the third interposer 30 in plan view. For example, the redistribution layer 85 may include the insulating layer 87 that extends so as to overlap the first interposer 10, the second interposer 20, and the third interposer 30 in plan view.

As illustrated in FIG. 48B, the conductive layer 86 of the redistribution layer 85 may include first wiring 86a for electrically connecting the first semiconductor element 40 and the second semiconductor element 45. The first wiring 86a may function as a power source line, may function as a ground line, or may function as a signal line. As illustrated in FIG. 48B, the first wiring 86a may extend in the first direction D1 from a position overlapping a first through via 14 of the first interposer 10 in plan view to a position overlapping a second through via 24 of the second interposer 20 in plan view. The first semiconductor element 40 and the second semiconductor element 45 may be electrically connected via the first through via 14, the first wiring 86a, and the second through via 24.

As illustrated in FIG. 48B, the conductive layer 86 of the redistribution layer 85 may include second wiring 86b for electrically connecting the first internal elements 70 and the second internal elements 75. The second wiring 86b may function as a power source line, may function as a ground line, or may function as a signal line. As illustrated in FIG. 48B, the second wiring 86b may extend in the first direction D1 from a position overlapping an electrode 71 of the first internal elements 70 in plan view to a position overlapping an electrode 76 of the second internal elements 75 in plan view.

As illustrated in FIG. 49, the redistribution layer 85 may include a plurality of redistribution layers 85A and 85B. That is to say, the redistribution layer 85 may be divided into the plurality of redistribution layers 85A and 85B.

The position at which the redistribution layer 85 is divided is not limited in particular. For example, as illustrated in FIG. 49, the redistribution layer 85A may be electrically connected to the first interposer 10 and the third interposer 30, and the redistribution layer 85B may be electrically connected to the second interposer 20 and the third interposer 30.

### Ninth Embodiment

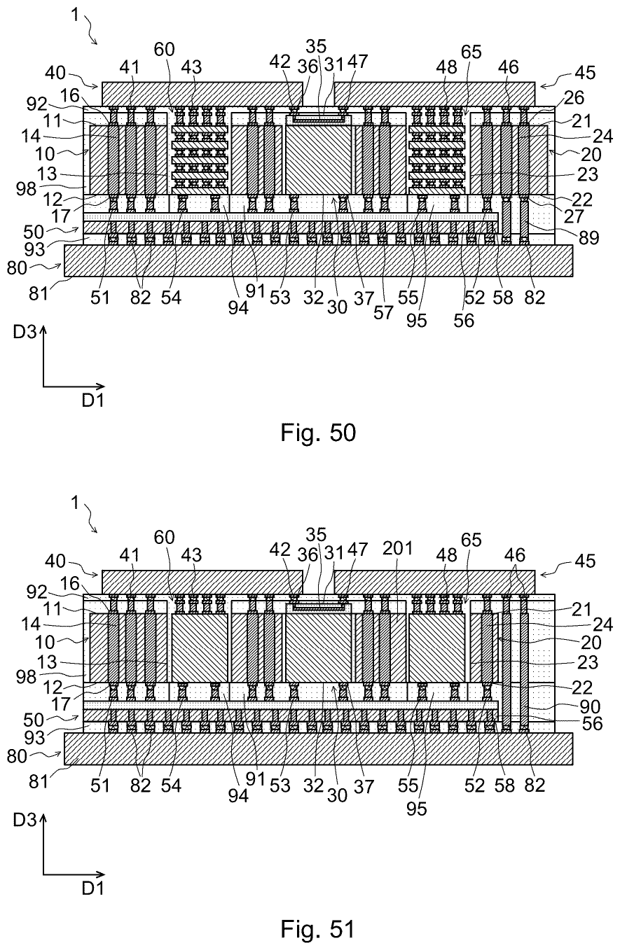

FIG. 50 and FIG. 51 are each a sectional view illustrating a semiconductor package 1 according to a ninth embodiment. The wiring substrate 80 may be electrically connected to the second interposer 20 or the second semiconductor element 45 without going through the third semiconductor element 50 or the redistribution layer 85.

For example, as illustrated in FIG. 50, the semiconductor package 1 may include conductive members 89 that extend in the third direction D3 between the pads 82 of the wiring substrate 80 and the pads 27 of the second interposer 20. The conductive members 89 do not have to overlap the third semiconductor element 50 in plan view.

For example, as illustrated in FIG. 51, the semiconductor package 1 may include conductive members 90 that extend in the third direction D3 between the pads 82 of the wiring substrate 80 and the fourth pads 46 of the second semiconductor element 45. The conductive members 90 do not have to overlap the second interposer 20 and the third semiconductor element 50 in plan view.

### Tenth Embodiment

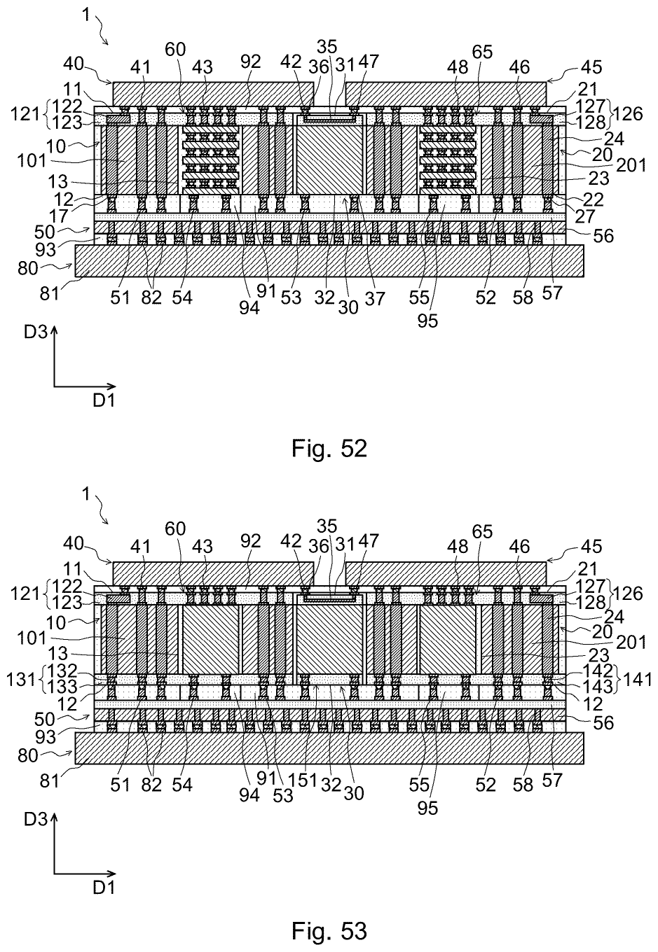

FIG. 52 and FIG. 53 are each a sectional view illustrating a semiconductor package 1 according to a tenth embodiment. The first interposer 10 may include a redistribution layer situated on the first face 11 or the second face 12.

For example, as illustrated in FIG. 52, the first interposer 10 may include a redistribution layer 121 situated on the first face 11. The redistribution layer 121 includes a conductive layer 122 and an insulating layer 123. The conductive layer 122 may extend from a position overlapping the first semiconductor element 40 to a position not overlapping the first semiconductor element 40 in plan view.

For example, as illustrated in FIG. 53, the first interposer 10 may include a redistribution layer 131 situated on the second face 12. The redistribution layer 131 includes a conductive layer 132 and an insulating layer 133.

The second interposer 20 may include a redistribution layer situated on the third face 21 or the fourth face 22.

For example, as illustrated in FIG. 52, the second interposer 20 may include a redistribution layer 126 situated on the third face 21. The redistribution layer 126 includes a conductive layer 127 and an insulating layer 128. The conductive layer 127 may extend from a position overlapping the second semiconductor element 45 to a position not overlapping the second semiconductor element 45 in plan view.

For example, as illustrated in FIG. 53, the second interposer 20 may include a redistribution layer 141 situated on the fourth face 22. The redistribution layer 141 includes a conductive layer 142 and an insulating layer 143.

Metals such as copper, gold, silver, platinum, rhodium, tin, aluminum, nickel, chromium or the like, or alloys using these, can be used as the material making up the conductive layers 122, 127, 132, and 142. Organic insulating materials such as polyimide, epoxy-based resin, acrylic-based resin, and so forth, can be used as the material making up the insulating layers 123, 128, 133, and 143.

As illustrated in FIG. 53, the third interposer 30 may include a redistribution layer 151 situated on the sixth face 32. The redistribution layer 151 includes a conductive layer and an insulating layer.

Metals such as copper, gold, silver, platinum, rhodium, tin, aluminum, nickel, chromium or the like, or alloys using these, can be used as the material making up the conductive layer. Organic insulating materials such as polyimide, epoxy-based resin, acrylic-based resin, and so forth, can be used as the material making up the insulating layer.

An example of a method for forming the redistribution layer 121 illustrated in FIG. 52 and FIG. 53 will be described.

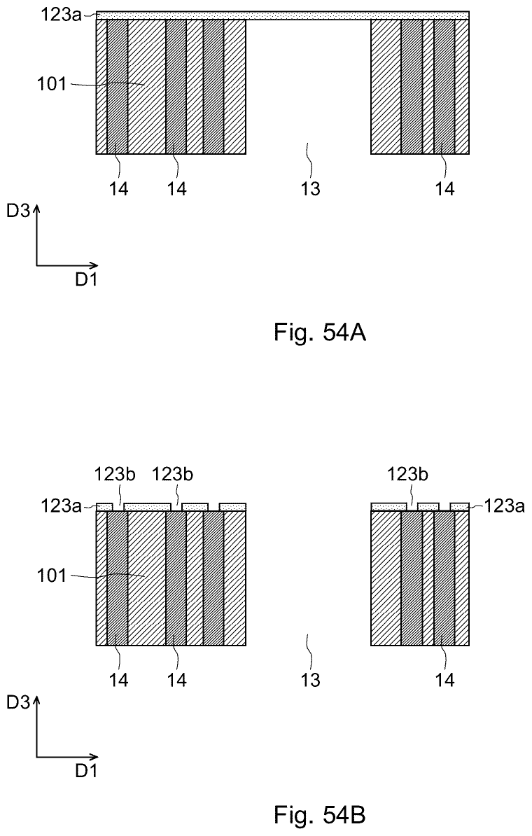

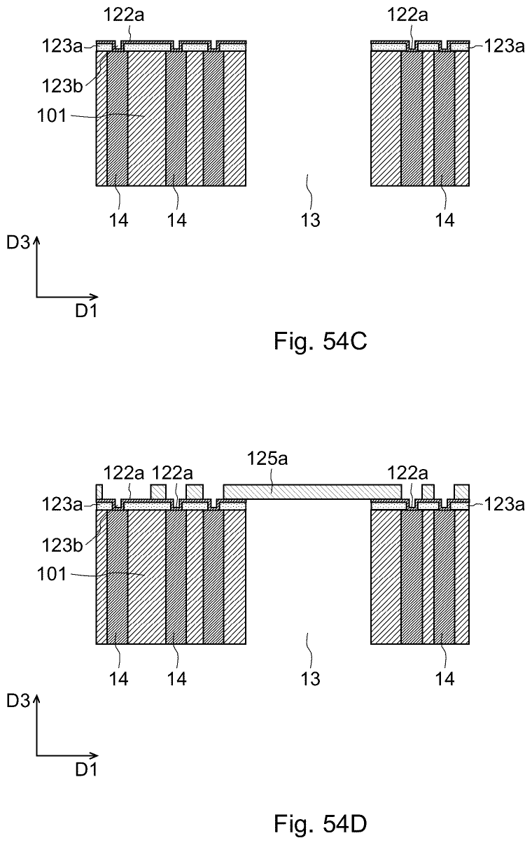

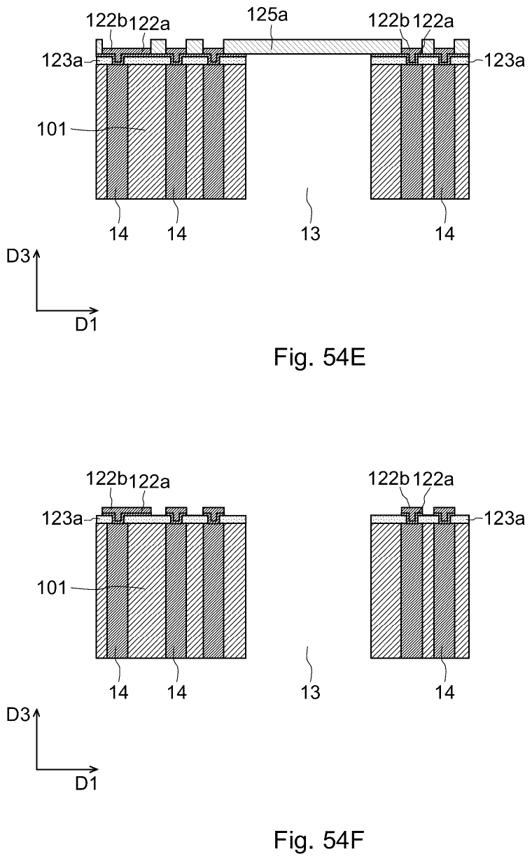

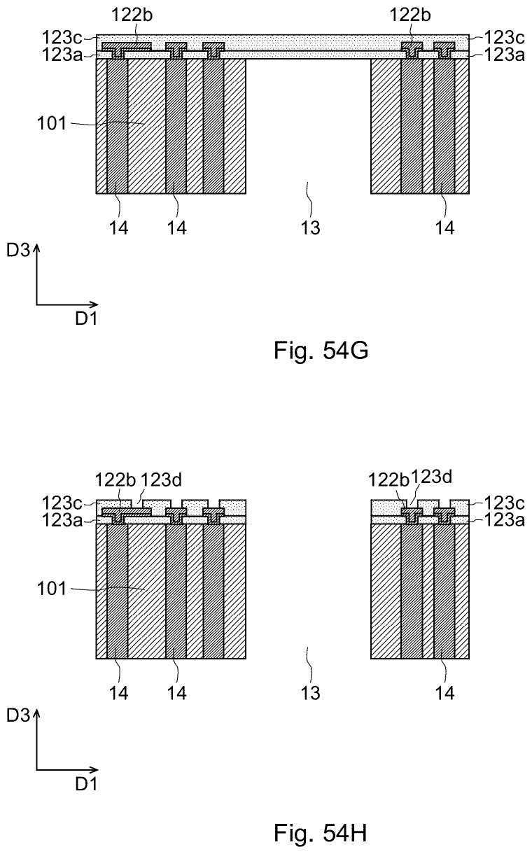

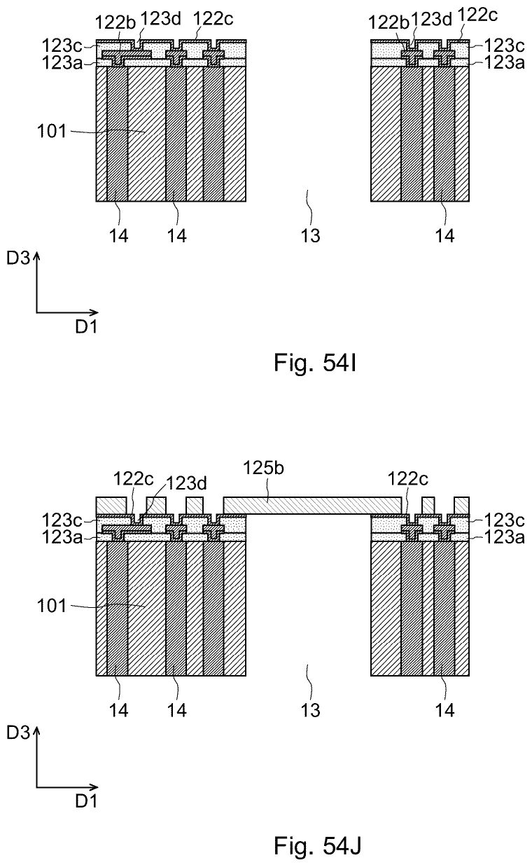

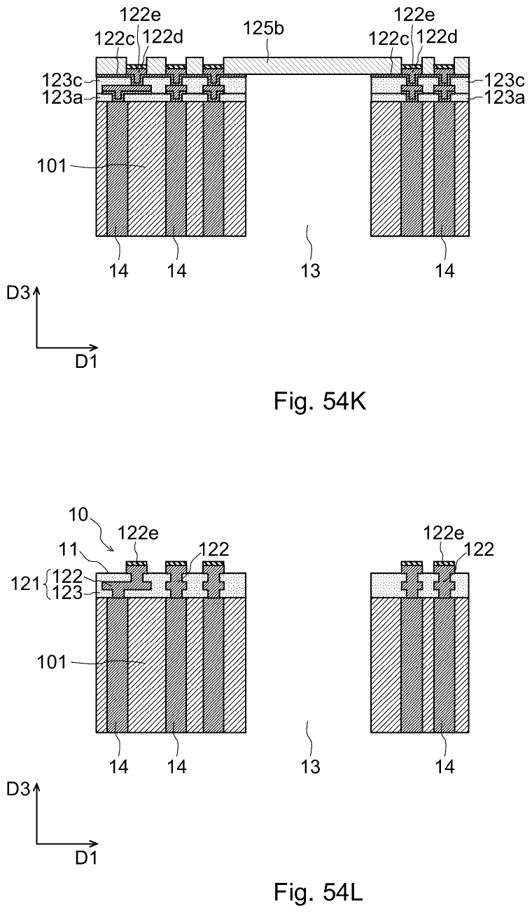

As illustrated in FIG. 54A, the substrate 101, including the first cavities 13 and the first through vias 14, is prepared. Subsequently, a first insulating layer 123a is formed on the substrate 101. The first insulating layer 123a contains the organic insulating material described above. The thickness of the first insulating layer 123a is, for example, 2 μm or more, and may be 5 μm or more. The thickness of the first insulating layer 123a is, for example, 20 μm or less, and may be 15 μm or less. The first insulating layer 123a may be formed by applying a film containing the organic insulating material onto the substrate 101. The first insulating layer 123a may be formed by coating a liquid containing the organic insulating material onto the substrate 101. In a case in which the first cavities 13 are formed in the substrate 101, the first insulating layer 123a is preferably formed using film.

Next, as illustrated in FIG. 54B, first openings 123b that overlap the first through vias 14 in plan view are formed in the first insulating layer 123a. The first openings 123b are formed by subjecting the first insulating layer 123a to exposing processing and developing processing, for example. As illustrated in FIG. 54B, the first insulating layer 123a over the first cavities 13 may be removed. Following the exposing processing and the developing processing, a step of baking the first insulating layer 123a may be carried out. The temperature in baking processing is 200° C. for example, and the time of the baking processing is one hour, for example.

Subsequently, as illustrated in FIG. 54C, a first seed layer 122a is formed on the surfaces of the first through vias 14 overlapping the first openings 123b. The first seed layer 122a may be formed on the surface of the first insulating layer 123a. The first seed layer 122a may contain metals such as titanium, copper, or the like, alloys using these, or layered arrangements thereof. The first seed layer 122a is formed by physical film formation methods such as sputtering, vapor deposition, or the like, for example. The thickness of the first seed layer 122a is, for example, 0.05 μm or more, and may be 0.10 μm or more. The thickness of the first seed layer 122a is, for example, 0.50 μm or less, and may be 0.30 am or less.

Subsequently, as illustrated in FIG. 54D, a first resist layer 125a is partially formed on the first seed layer 122a. The first resist layer 125a has openings overlapping the first openings 123b in plan view. The first resist layer 125a is formed by subjecting the film containing the organic insulating material to exposing processing and developing processing, for example.

Subsequently, as illustrated in FIG. 54E, a first plating layer 122b is formed by electrolytic plating on the first seed layer 122a at the openings of the first resist layer 125a. The first plating layer 122b may contain copper as a primary component thereof. For example, the first plating layer 122b may contain 80% by mass or more of copper. The thickness of the first plating layer 122b is, for example, 2 μm or more, and may be 3 μm or more. The thickness of the first plating layer 122b is, for example, 10 μm or less, and may be 5 μm or less.

Next, as illustrated in FIG. 54F, the first resist layer 125a is removed. For example, the first resist layer 125a may be removed using an organic solvent. Also, the first seed layer 122a over the first resist layer 125a is removed. The first seed layer 122a may be removed using an alkaline chemical when the first seed layer 122a contains titanium. The first seed layer 122a may be removed using an acidic chemical when the first seed layer 122a contains copper.

Subsequently, as illustrated in FIG. 54G, a second insulating layer 123c is formed on the first insulating layer 123a and the first plating layer 122b. The second insulating layer 123c may, in the same ways as the first insulating layer 123a, be formed using a film containing the organic insulating material, or be formed using a liquid containing the organic insulating material. The thickness of the second insulating layer 123c is, for example, 2 μm or more, and may be 5 μm or more. The thickness of the second insulating layer 123c is, for example, 20 μm or less, and may be 15 μm or less.

Next, as illustrated in FIG. 54H, second openings 123d that overlap the first plating layer 122b in plan view are formed in the second insulating layer 123c. The second openings 123d are formed by subjecting the second insulating layer 123c to exposing processing and developing processing, for example, in the same way as the first openings 123b. As illustrated in FIG. 54H, the second insulating layer 123c over the first cavities 13 may be removed. Following the exposing processing and the developing processing, a step of baking the second insulating layer 123c may be carried out. The temperature in the baking processing is 200° C. for example, and the time of the baking processing is one hour, for example.

Subsequently, as illustrated in FIG. 54I, a second seed layer 122c is formed on the surface of the first plating layer 122b overlapping the second openings 123d. The second seed layer 122c may be formed on the surface of the second insulating layer 123c. The second seed layer 122c may contain metals such as titanium, copper, or the like, alloys using these, or layered arrangements thereof, in the same way as the first seed layer 122a. The second seed layer 122c is formed by physical film formation methods such as sputtering, vapor deposition, or the like, for example. The thickness of the second seed layer 122c is, for example, 0.05 μm or more, and may be 0.10 μm or more. The thickness of the second seed layer 122c is, for example, 0.50 μm or less, and may be 0.30 μm or less.

Subsequently, as illustrated in FIG. 54J, a second resist layer 125b is partially formed on the second seed layer 122c. The second resist layer 125b has openings overlapping the second openings 123d in plan view. The second resist layer 125b is formed by subjecting the film containing the organic insulating material to exposing processing and developing processing, for example, in the same way as the first resist layer 125a.

Subsequently, as illustrated in FIG. 54K, a second plating layer 122d is formed by electrolytic plating on the second seed layer 122c at the openings of the second resist layer 125b. The second plating layer 122d may contain copper as a primary component thereof. For example, the second plating layer 122d may contain 80% by mass or more of copper. The thickness of the second plating layer 122d is, for example, 2 μm or more, and may be 3 μm or more. The thickness of the second plating layer 122d is, for example, 10 μm or less, and may be 5 μm or less.

The second plating layer 122d may protrude from the insulating layer 123 in the third direction D3. The second plating layer 122d can function as a pad.

As illustrated in FIG. 54K, a surface layer 122e may be formed on the second plating layer 122d. The surface layer 122e may contain metals such as nickel, gold, and so forth, alloys using these, or layered arrangements thereof. For example, the surface layer 122e may include a layer of nickel, and a layer of gold situated on the layer of nickel. The layer of nickel has a thickness of, for example, 0.2 μm. The layer of gold has a thickness of, for example, 0.1 μm. The surface layer 122e may be formed by electrolytic plating.

Subsequently, as illustrated in FIG. 54L, the second resist layer 125b is removed. For example, the second resist layer 125b may be removed using an organic solvent. Also, the second seed layer 122c over the second resist layer 125b is removed. The second seed layer 122c may be removed using an alkaline chemical when the second seed layer 122c contains titanium. The second seed layer 122c may be removed using an acidic chemical when the second seed layer 122c contains copper. Thus, the redistribution layer 121 including the conductive layer 122 and the insulating layer 123 is formed.

In the example of FIG. 54A to FIG. 54L, the conductive layer 122 includes at least the first seed layer 122a, the first plating layer 122b, the second seed layer 122c, and the second plating layer 122d. The conductive layer 122 may include the surface layer 122e. In FIG. 54L, the first seed layer 122a, the first plating layer 122b, the second seed layer 122c, and the second plating layer 122d are drawn as an integral layer.

In the example of FIG. 54A to FIG. 54L, the insulating layer 123 includes at least the first insulating layer 123a and the second insulating layer 123c. In FIG. 54L, the first insulating layer 123a and the second insulating layer 123c are drawn as an integral layer.

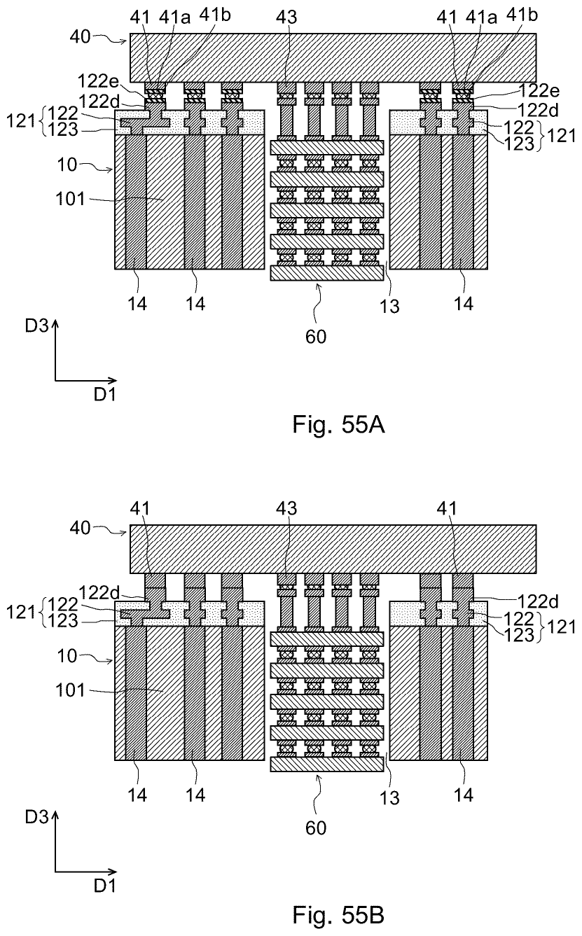

FIG. 55A is a diagram for describing an example of a method for connecting the redistribution layer 121 to the first semiconductor element 40. The conductive layer 122 of the redistribution layer 121 may be electrically connected to the first pads 41 of the first semiconductor element 40 via bumps 41b. In this case, the conductive layer 122 may include the surface layer 122e situated on the second plating layer 122d. The surface layer 122e may be in contact with the bumps 41b. In the same way, the first pads 41 of the first semiconductor element 40 may include a surface layer 41a that is in contact with the bumps 41b. The surface layer 41a may contain metals such as nickel, gold, and so forth, alloys using these, or layered arrangements thereof, in the same way as the surface layer 122e. For example, the surface layer 122e may include a layer of nickel, and a layer of gold situated on the layer of nickel.

FIG. 55B is a diagram for describing an example of a method for connecting the redistribution layer 121 to the first semiconductor element 40. The conductive layer 122 of the redistribution layer 121 may be directly connected to the first pads 41 of the first semiconductor element 40. For example, the second plating layer 122d of the conductive layer 122 may be directly connected to the first pads 41 of the first semiconductor element 40. In this case, the first pads 41 may contain 80% by mass or more of copper, in the same way as the second plating layer 122d.

A plurality of components disclosed in the above embodiments and modifications can be appropriately combined as necessary. Alternatively, several components may be omitted from the entirety of components described in the above embodiments and modifications.

### EXAMPLES

Next, embodiments of the present disclosure will be described in further detail by way of Examples, but the embodiments of the present disclosure are not limited to the descriptions of the Examples below, unless surpassing the spirit thereof.

### Example 1

The semiconductor package 1 such as illustrated in FIG. 20, including the first interposer 10 including the first cavities 13, the second interposer 20 including the second cavities 23, the third interposer 30, the first semiconductor element 40, and the second semiconductor element 45, was fabricated. Detailed structures of the components are as follows.
Dimensions of first interposer 10 in first direction D1: 20 mm
Dimensions of second interposer 20 in first direction D1: 20 mm
Dimensions of third interposer 30 in first direction D1: 5 mm
Spacing S1 between first interposer 10 and third interposer 30: 0.1 mm or more and 0.5 mm or less
Spacing S2 between second interposer 20 and third interposer 30: 0.1 mm or more and 0.5 mm or less
Material of substrates of interposers 10, 20, 30: glass
Thickness of substrates of interposers 10, 20, 30: 0.4 mm
Width of first portion 351 of wiring 35: 0.4 μm to 20 μm
Length of first portion 351 of wiring 35: 3 mm
Thickness of first portion 351 of wiring 35: 3 μm
Dimension of second portions 352 of wiring 35: 5 μm

The width of the first portion 351 so the dimension of the first portion 351 in a direction that is orthogonal to the direction in which the first portion 351 extends in plan view. The length of the first portion 351 is the dimension of the first portion 351 in the direction in which the first portion 351 extends in plan view. The dimension of the second portion 352 is the greatest value of the dimension of the second portion 352 in plan view. In a case in which the second portion 352 has a circular shape in plan view, the dimension of the second portion 352 is the diameter of the second portion 352 in plan view.

Next, the semiconductor package 1 was subjected to a thermal cycle test for 1000 cycles. One cycle includes a temperature increase process from −55° C. to 125° C., and a temperature decrease process from 125° C. to −55° C.

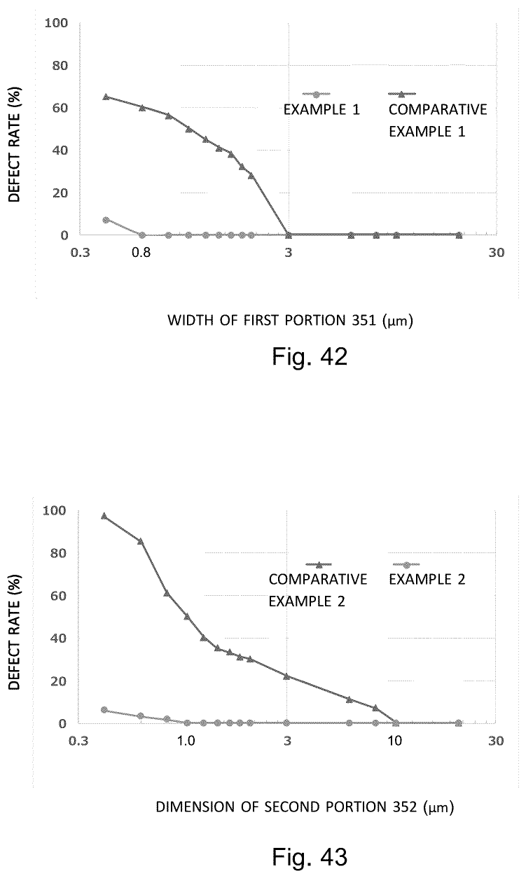

Next, whether or not the first semiconductor element 40 and the second semiconductor element 45 were electrically connected via the wiring 35 was inspected. That is to say, whether or not line breakage occurred in the wiring 35 was inspected. The results are indicated by round markers in FIG. 42. The horizontal axis is the width of the first portion 351. The vertical axis is defect rate. The defect rate is the proportion of the semiconductor packages 1 exhibiting line breakage in a case of subjecting a plurality of semiconductor packages 1 having the same width of the first portion 351 to the thermal cycle test. As shown in FIG. 42, no line breakage occurred in a case in which the width of the first portion 351 was 0.8 μm or more.

### Comparative Example 1

The semiconductor package 1 was fabricated in the same way as the case of Example 1, except for the substrate of the first interposer 10, the substrate of the second interposer 20, and the substrate of the third interposer 30 being a single common substrate. Also, the semiconductor package 1 was subjected to a thermal cycle test for 1000 cycles, in the same way as the case of Example 1. The results are indicated by triangular markers in FIG. 42. As shown in FIG. 42, line breakage occurred in a case in which the dimension of the second portions 352 was less than 3 μm.

### Example 2

The semiconductor package 1 was fabricated in the same way as the case of Example 1, except that the width of the first portion 351 of the wiring 35 was set to 2 μm, and the dimension of the second portion 352 was varied within the range of 0.4 μm to 20 μm. Also, the semiconductor package 1 was subjected to a thermal cycle test for 1000 cycles, in the same way as the case of Example 1. The results are indicated by round markers in FIG. 43. The horizontal axis is the dimension of the second portion 352. The vertical axis is the defect rate. The defect rate is the proportion of the semiconductor packages 1 exhibiting line breakage in a case of subjecting a plurality of semiconductor packages 1 having the same dimension of the second portion 352 to the thermal cycle test. As shown in FIG. 43, no line breakage occurred in a case in which the dimension of the second portion 352 was 1.0 μm or more.

### Comparative Example 2

The semiconductor package 1 was fabricated in the same way as the case of Example 2, except for the substrate of the first interposer 10, the substrate of the second interposer 20, and the substrate of the third interposer 30 being a single common substrate. Also, the semiconductor package 1 was subjected to a thermal cycle test for 1000 cycles, in the same way as the case of Example 2. The results are indicated by triangular markers in FIG. 43. As shown in FIG. 43, line breakage occurred in a case in which the dimension of the second portions 352 was less than 10 μm.

### Comparative Example 3

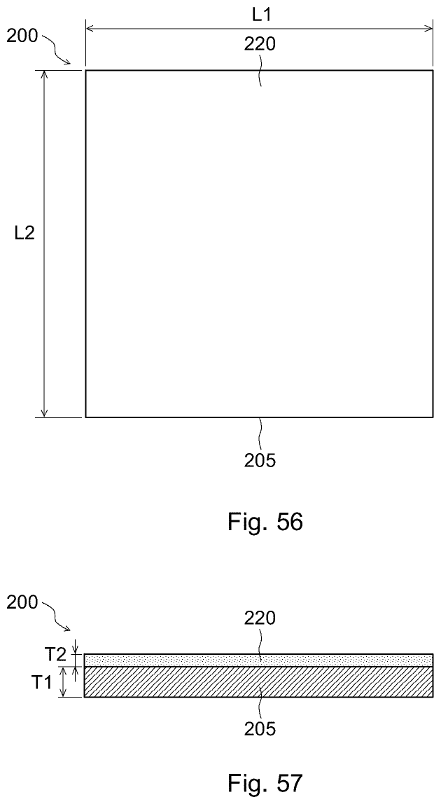

The amount of warping occurring in a stacked assembly 200 illustrated in FIG. 56 was calculated on the basis of simulation. The shape of the stacked assembly 200 is a rectangle that includes first sides having a length L1 and second sides having a length L2 in plan view. Length L1 and length L2 are both 40 mm.

FIG. 57 is a sectional view of the stacked assembly 200. The stacked assembly 200 includes a substrate 205 having a thickness T1, and an insulating layer 220 having a thickness T2. The insulating layer 220 extends over the entire region of the substrate 205. The substrate 205 is made of glass. The insulating layer 220 is made of polyimide. The thickness T1 is 400 μm. The thickness T2 is 35 μm.

The amount of warping occurring in the stacked assembly 200 was 361 μm at the greatest.

### Example 3

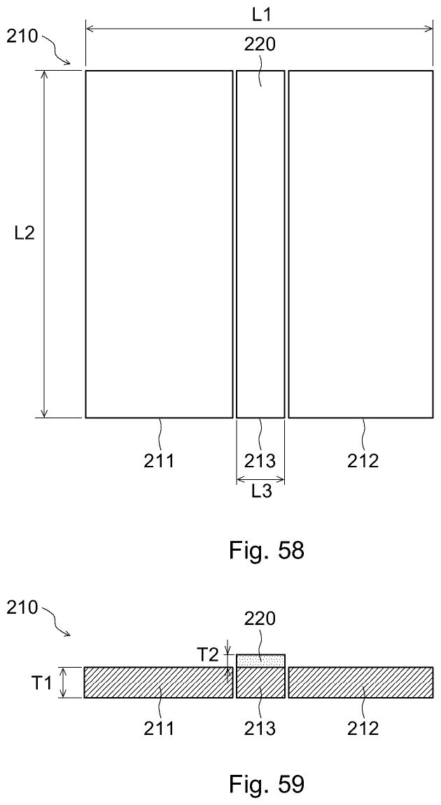

The amount of warping occurring in a stacked assembly 210 illustrated in FIG. 58 was calculated on the basis of simulation. FIG. 59 is a sectional view of the stacked assembly 210. The stacked assembly 210 differs from the stacked assembly 200 illustrated in FIG. 56 with regard to the point that the substrate is divided into three substrates 211, 212, and 213, and the point that no insulating layer 220 is provided on the substrates 211 and 212. Width L3 of the substrate 213 on which the insulating layer 220 is provided is 5 mm. The lengths L1 and L2, and the thicknesses T1 and T2 are the same as the case of the stacked assembly 200.

The amount of warping occurring in the stacked assembly 210 was 183 μm at the greatest. Dividing the substrate and limiting the region of the insulating layer enabled the amount of warping to be reduced as compared with the case of the stacked assembly 200.

### REFERENCE SIGNS LIST

1 semiconductor package
10 first interposer
11 first face
12 second face
13 first cavity
14 first through via
18 cavity
20 second interposer
21 third face
22 fourth face
23 second cavity
24 second through via
28 cavity
30 third interposer
31 fifth face
32 sixth face
34 third through via
35 wiring
38 cavity
40 first semiconductor element
45 second semiconductor element
50 third semiconductor element
56 substrate
57 insulating layer
58 electrode
60 first internal semiconductor element
65 second internal semiconductor element
70 first internal element
75 second internal element
80 wiring substrate
81 substrate
82 pad
85 redistribution layer
86 conductive layer
87 insulating layer
89 conductive member
90 conductive member

1. A semiconductor package, comprising:
a first interposer that includes a first face and a second face situated on an opposite side from the first face;
a second interposer that includes a third face and a fourth face situated on an opposite side from the third face, and that is arrayed with the first interposer in a first direction;
a third interposer that includes a fifth face and a sixth face situated on an opposite side from the fifth face, and that is situated between the first interposer and the second interposer in the first direction;
a first semiconductor element that overlaps the first face and the fifth face in plan view; and
a second semiconductor element that overlaps the third face and the fifth face in plan view, wherein
the third interposer includes wiring that electrically connects the first semiconductor element and the second semiconductor element.

2. The semiconductor package according to claim 1, wherein
the first interposer includes a first cavity, and
the semiconductor package further comprises a first internal semiconductor element that is situated in the first cavity.

3. The semiconductor package according to claim 2, wherein
the first cavity is formed in the first face, and
the first internal semiconductor element is electrically connected to the first semiconductor element.

4. (canceled)

5. (canceled)

6. The semiconductor package according to claim 1, further comprising a third semiconductor element that overlaps the second face, the fourth face, and the sixth face in plan view.

7. The semiconductor package according to claim 6, further comprising a wiring substrate that includes a substrate and a pad that is electrically connected to the third semiconductor element.

8. The semiconductor package according to claim 7, wherein the substrate contains an organic material.

9. The semiconductor package according to claim 6, wherein
the first interposer includes a cavity formed in the second face, and
the semiconductor package further comprises a first internal element that is situated in the cavity formed in the second face and that is electrically connected to the third semiconductor element.

10. (canceled)

11. The semiconductor package according to any one of claim 1, wherein the first interposer includes a first through via.

12. (canceled)

13. The semiconductor package according to any one of claim 1, wherein the third interposer includes a third through via.

14. The semiconductor package according to any one of claim 1, wherein
the third interposer includes a redistribution layer that is situated on the fifth face, and that includes an insulating layer and wiring, and
the insulating layer contains an organic insulating material.

15. The semiconductor package according to claim 14, wherein the organic insulating material contains polyimide, epoxy-based resin, or acrylic-based resin.

16. The semiconductor package according to claim 14, wherein the insulating layer contains a filler made of an inorganic material.

17. The semiconductor package according to claim 1, wherein
the first interposer includes a first substrate made of an inorganic material,
an insulating layer containing an organic insulating material is not provided on the faces of the first substrate of the first interposer,
the second interposer includes a second substrate made of an inorganic material, and
an insulating layer containing an organic insulating material is not provided on the faces of the second substrate of the second interposer.

18. The semiconductor package according to any one of claim 1, wherein
the first interposer includes a first substrate made of an inorganic material, and a redistribution layer that is situated on one of the faces of the first substrate and that includes an insulating layer and wiring, and
the second interposer includes a second substrate made of an inorganic material, and a redistribution layer that is situated on one of the faces of the second substrate and that includes an insulating layer and wiring.

19. A manufacturing method of a semiconductor package, the manufacturing method comprising:
a disposing step of disposing a first interposer that includes a first face and a second face situated on an opposite side from the first face, a second interposer that includes a third face and a fourth face situated on an opposite side from the third face, and a third interposer that includes a fifth face and a sixth face situated on an opposite side from the fifth face;
a first mounting step of mounting a first semiconductor element so as to overlap the first face and the fifth face in plan view; and
a second mounting step of mounting a second semiconductor element so as to overlap the third face and the fifth face in plan view, wherein
the second interposer is arrayed with the first interposer in a first direction,
the third interposer is situated between the first interposer and the second interposer in the first direction, and
the third interposer includes wiring that electrically connects the first semiconductor element and the second semiconductor element.

20. The manufacturing method according to claim 19, wherein
the first interposer includes a first cavity, and
the first mounting step includes a step of disposing, in the first cavity, a first internal semiconductor element that is connected to the first semiconductor element.

21. (canceled)

22. The manufacturing method according to any one of claim 19, further comprising:
a preparation step of preparing a third semiconductor element, wherein,
in the disposing step, the first interposer, the second interposer, and the third interposer are disposed such that the second face, the fourth face, and the sixth face overlap the third semiconductor element in plan view.

23. The manufacturing method according to claim 22, further comprising a step of disposing a wiring substrate including a substrate and a pad, such that the pad of the wiring substrate is electrically connected to the third semiconductor element.

24. The manufacturing method according to claim 22, further comprising a step of mounting a first internal element in the third semiconductor element, wherein
the disposing step includes a step of disposing the first interposer such that the first internal element is situated in a cavity formed in the second face.

25. (canceled)

26. An interposer group onto which a first semiconductor element and a second semiconductor element are mounted, the interposer group comprising:
a first interposer that includes a first face and a second face situated on an opposite side from the first face;
a second interposer that includes a third face and a fourth face situated on an opposite side from the third face, and that is arrayed with the first interposer in a first direction; and
a third interposer that includes a fifth face and a sixth face situated on an opposite side from the fifth face, and that is situated between the first interposer and the second interposer in the first direction, wherein
the first semiconductor element is mounted so as to overlap the first face and the fifth face in plan view,
the second semiconductor element is mounted so as to overlap the third face and the fifth face in plan view, and
the third interposer includes wiring that electrically connects the first semiconductor element and the second semiconductor element.
